(19) United States
(12) Patent Application Publication
(10) Pub. No.: US 2023/0012274 A1
(43) Pub. Date: Jan. 12, 2023

(54) WATER-REDISPERSIBLE GRAPHENE POWDER

(71) Applicant: ROYAL MELBOURNE INSTITUTE OF TECHNOLOGY, Melbourne, Victoria (AU)

(72) Inventors: Tuan Sang TRAN, Sunshine North, Victoria (AU); Namita ROY CHOUDHURY, Docklands, Victoria (AU); Naba DUTTA, Golden Grove, South Australia (AU)

(21) Appl. No.: 17/756,696

(22) PCT Filed: Nov. 27, 2020
(86) PCT No.: PCT/AU2020/051292

§ 371 Date: May 31, 2022

(30) Foreign Application Priority Data
Nov. 29, 2019 (AU) 2019904516

(51) Int. Cl. C01B 32/194; C09D 17/00; C09D 11/037; C09D 11/033; C09D 11/52; H05K 1/02; H05K 1/09; H05K 3/12; B33Y 80/00; B33Y 10/00; D01F 9/12; D01D 5/06

(52) U.S. Cl. CPC C01B 32/194; C09D 17/001; C09D 17/004; C09D 11/037; C09D 11/033; C09D 11/52; H05K 1/0277; H05K 1/092; H05K 3/12; B33Y 80/00; B33Y 10/00; D01F 9/12; D01D 5/06; C01B 2204/22; C01B 2204/04; C01B 2204/32; C01B 2204/28; C01P 2004/24; C01P 2002/84; C01P 2002/88; C01P 2004/04; C01P 2004/03; C01P 2002/82; C01P 2002/85; D10B 2101/12

(57) ABSTRACT

The invention described herein provides a dry graphene powder composition comprising pristine graphene flakes, wherein the pristine graphene flakes are non-covalently functionalised with polymeric amphiphilic molecules and wherein the dry graphene powder composition is capable of forming a stable homogeneous dispersion in aqueous or alcoholic media, in the absence of free dispersants or stabilizers, as well as methods for producing same, and the use thereof in graphene inks, for 2D and 3D printing, for production of flexible circuits, electrodes, electrocatalysts, for fabrication of nanocomposites and for wet-spinning of pristine graphene fibers.

### TECHNICAL FIELD

The present invention provides a dry pristine graphene powder that is stable and redispersible, methods for the manufacture thereof, as well as uses and applications thereof in stable homogeneous dispersions, graphene inks, 2D and 3D printing, flexible circuits, electrodes, electrocatalysts, nanocomposites and wet-spinning of pristine graphene fibers.

### BACKGROUND ART

Graphene is an allotrope of carbon comprising a single layer of atoms in a two-dimensional hexagonal lattice. It is the basic structural element of other carbon allotropes, including graphite, charcoal, carbon nanotubes and fullerenes. It can also be thought of as an indefinitely large, flat aromatic molecule.

Graphene has unique properties which set it apart from other allotropes of carbon. In proportion to its thickness, it is about 100 times stronger than the strongest steel. However, its density is dramatically lower than any steel, with a mass of 0.763 mg per square meter. Graphene conducts heat and electricity very efficiently and is nearly transparent. Graphene also shows a large and nonlinear diamagnetism, exceeding that of graphite.

Owing to its two-dimensional nature and unprecedented properties, graphene has attracted enormous attention in the scientific and technological fields [1,2]. Over the past decade, graphene has found significance in a wide spectrum of fields, including energy [3-5], biomedical [6,7], environmental [8,9] and electronics [10-12]. Nevertheless, the industrial applications of graphene are still hindered by the lack of mass production techniques to meet the various challenges and requirements that the handling and manufacturing of graphene imposes, especially in some important areas such as printed electronics and smart coatings [10,13]. Therefore, a scalable production strategy for producing high quality graphene in a processable, stable and easily transportable form is highly desirable.

Among the available graphene preparation methods developed so far, liquid phase exfoliation of graphite has a proven track record as the most viable approach for the bulk production of high quality graphene due to its cost-effectiveness, simplicity, and scalability [14,15]. The principle underlying liquid-phase exfoliation relies on overcoming the π-π interactions between stacked graphite layers for the extraction of individual sheets in a liquid medium by means of sonication or high-shear rate [15,16]. With respect to the dispersive London interactions of graphite, the potential energy between adjacent layers of graphene is significantly reduced when immersed in a liquid medium matching its surface energy [17,18]. Therefore, solvents with similar surface energies to that of graphite, such as n-methyl-2-pyrrolidone (NMP) and n,n-dimethylformamide (DMF), are extensively used for liquid-phase exfoliation [18]. Solvents such as NMP and DMF also effectively act as dispersants or stabilizers and stabilize the exfoliated flakes against aggregation in liquid media. However, these solvents are expensive and highly toxic. They also have significantly higher boiling points than that of water and therefore require excessive heat and/or energy to remove when used in graphene printing and related graphene manufacturing processes. Their industrial use has raised significant environmental concerns, which has been subjected to strict regulations in the European Union [19]. For this reason, there is a critical need for cheaper and more sustainable alternatives to these toxic, high boiling point solvents that are subject to stringent environmental and safety standards.

Recently, research efforts have shifted toward the use of water for liquid-phase exfoliation, the most preferable solvent from an environmental safety and manufacturing perspective, due to its low-cost and non-toxic nature. For similar reasons, alcoholic solvents, particularly lower alcohols such as methanol, ethanol and propanol represent attractive prospective targets for graphene exfoliation and/or dispersions of graphene, as they are cheap, relatively non-toxic (compared to NMP and DMF for example), and come with the added benefit of even lower boiling points than water. However, lower alcohols are still relatively polar and present challenges in terms of achieving higher dispersion concentrations of graphene as a result of its hydrophobic properties.

Due to the intrinsic hydrophobicity of graphite, an added dispersant or stabilizer component such as a surfactant [20] or polymer [21] is required to promote exfoliation and stabilize the exfoliated flakes against aggregation in aqueous media. Surfactants such as sodium cholate (SC), sodium dodecylsulfate (SDS), sodium dodecylbenzene sulfonate (SDBS), Pluronic F-127, and Triton X-100 can be used to produce graphene dispersions in water. However, the proportions of surfactants in the dispersions are usually higher than the graphene itself and therefore, the surfactants themselves become contaminants for the graphene dispersions. Polymers such as polymethyl methacrylate (PMMA), polyvinyl alcohol (PVA), polyvinyl pyrrolidone (PVP), ethyl cellulose (EC), and many more can be used to prepare stable graphene dispersions in many different solvents, including water. Similar to surfactants, the proportions of these polymers in the dispersions are usually higher than the graphene itself and they therefore become contaminants for graphene dispersions.

The presence of these dispersant or stabilizer compounds in the graphene dispersions is undesirable, especially for electronics and medical device applications, where dispersants or stabilizer compounds become contaminants [22]. Therefore, it is essential to develop new approaches to disperse graphene in aqueous medium in the absence of excessive dispersants or stabilizers.

Furthermore, graphene dispersions are generally only available commercially as pre-prepared liquid dispersions, which increases the cost for storage and transportation, and also presents difficulties in terms of maintaining the stability or homogeneity of the dispersion over time. This is in many respects due to the fact that by nature, graphene is a hydrophobic material and therefore, it cannot be dispersed in water alone. As pristine graphene cannot be dispersed in water alone, excessive surfactants and/or polymers (stabilisers or dispersants), or toxic and high boiling point solvents are added to ameliorate water's surface tension and/or polarity, or to form emulsion systems that can stabilize graphene in the dispersions. When such graphene dispersions are processed utilizing casting, coating, and/or printing, the excessive surfactants/polymers/high boiling solvents (dispersants or stabilisers) are removed afterward by washing and/or chemical etching. However, removing the high concentrations of dispersants or stabilisers also negatively affects the quality of the deposited graphene in the system.

It would therefore be highly advantageous to provide a pristine graphene in dry powder form that is sufficiently hydrophilic to be capable of being re-dispersed in aqueous or alcoholic media without the need for excessive dispersants or stabilisers.

It is against this background that the present invention has been developed.

The above discussion of the background art is intended to facilitate an understanding of the present invention only. The discussion is not an acknowledgement or admission that any of the material referred to is or was part of the common general knowledge as at the priority date of the application.

### SUMMARY OF INVENTION

Provided herein is a water-redispersible, alcohol-redispersible or water/alcohol redispersible dry pristine graphene powder based on 7—stacking adsorption of amphiphilic molecules, which shows unprecedented capabilities to formulate stable and concentrated graphene dispersions in aqueous or alcoholic solutions, suitable for a wide range of applications.

In one aspect, the invention provides a dry graphene powder composition comprising; pristine graphene flakes, wherein the pristine graphene flakes are non-covalently functionalised with polymeric amphiphilic molecules; and wherein the dry graphene powder composition is capable of forming a stable homogeneous dispersion in aqueous or alcoholic media, in the absence of free dispersants or stabilizers.

In one aspect, the invention provides a dry graphene powder composition comprising; pristine graphene flakes, wherein the pristine graphene flakes are non-covalently functionalised with polymeric amphiphilic molecules; and wherein the dry graphene powder composition is capable of forming a stable homogeneous dispersion in an alcohol/water mixture.

In one aspect, the invention provides a dry graphene powder composition comprising; pristine graphene flakes, wherein the pristine graphene flakes are non-covalently functionalised with polymeric amphiphilic molecules; and wherein the dry graphene powder composition is capable of forming a stable homogeneous dispersion in pure water.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules comprise a terminal aromatic moiety or conjugated double-bond moiety for non-covalently functionalising the pristine graphene flakes via π-π stacking adsorption thereto.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules comprise a terminal and optionally ionisable polar moiety for imparting hydrophilicity to the pristine graphene flakes.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules with a molecular weight within the range of 5 to 100 KDa, or any sub-range falling within the range of 5 to 100 KDa.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I;

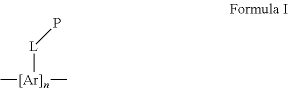

wherein;
Ar is an aromatic moiety;
P is an optionally ionisable polar moiety or a salt thereof;
n is an integer of between 20 and 350;
L is a linker independently selected from the group consisting of; a bond, C₁₋₂₀alkanediyl, C₁₋₂₀heteroalkanediyl, C₁₋₂₀alkenediyl, C₁₋₂₀heteroalkenediyl, C₁₋₂₀alkynediyl, and C₁₋₂₀heteroalkynediyl.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein Ar is a substituted or unsubstituted aromatic moiety independently selected from the group consisting of; thienyl, phenyl, biphenyl, naphthyl, indanyl, indenyl, fluorenyl, pyrenyl, pyridyl, pyrazinyl, pyrimidinyl, pyrrolyl, pyrazolyl, imidazolyl, thiazolyl, oxazolyl, isooxazolyl, thiadiazolyl, triazolyl, oxadiazolyl, thiophenyl, furanyl, quinolinyl, indolyl, and isoquinolinyl moieties.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein P is a polar moiety independently selected from the group consisting of; sulfonate, carboxylate, nitrate, sulfate, carboxamide, amine, substituted amine, quaternary amine, hydroxy, alkyloxy, sulphide, thiol, nitro, and nitrile moieties.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein Ar is thienyl.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein P is sulfonate, carboxylate or salts thereof.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein L is —C₁₋₈alkyl—O—C₁₋₈alkyl—, or —C₁₋₈alkyl-.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein L is −2-ethyloxy-4-butyl-, or methylene.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein the compound of Formula I is poly-[2-(3-thienyl)ethyloxy-4-butylsulfonate] sodium salt (PTEBS), or poly-(3-thiophene acetic acid) (PTAA);

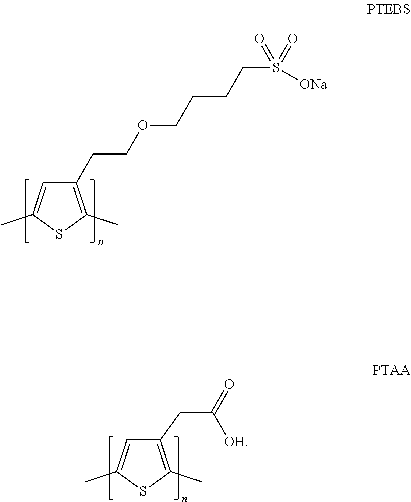

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules comprise less than 50% by weight of the composition.

In one aspect, the invention provides a dry graphene powder composition comprising; pristine graphene flakes, wherein the pristine graphene flakes are non-covalently functionalised with polymeric amphiphilic molecules; and wherein the polymeric amphiphilic molecules comprise approximately 2% by weight of the composition.

In one aspect, the invention provides a dry graphene powder composition comprising; pristine graphene flakes, wherein the pristine graphene flakes are non-covalently functionalised with polymeric amphiphilic molecules; and wherein the conductivity measured as sheet resistance of a dried thin film prepared therefrom is better than 350 Ω/sq.

In one aspect, the invention provides a dry graphene powder composition comprising; pristine graphene flakes, wherein the pristine graphene flakes are non-covalently functionalised with polymeric amphiphilic molecules; and wherein the conductivity measured as sheet resistance of a dried thin film prepared therefrom is better than 35 Ω/sq.

In one aspect, the invention provides a dry graphene powder composition comprising; pristine graphene flakes, wherein the pristine graphene flakes are non-covalently functionalised with polymeric amphiphilic molecules; and wherein the conductivity measured as sheet resistance of a dried thin film prepared therefrom is approximately 30 Ω/sq.

In one aspect, the invention provides a dry graphene powder composition comprising; pristine graphene flakes, wherein the pristine graphene flakes are non-covalently functionalised with polymeric amphiphilic molecules; and wherein the pristine graphene flakes have a height profile as determined by Atomic Force Microscopy of approximately 1 nm.

In one aspect, the invention provides a dry graphene powder composition comprising; pristine graphene flakes, wherein the pristine graphene flakes are non-covalently functionalised with polymeric amphiphilic molecules; and wherein the lateral size of at least 50% of the pristine graphene flakes as determined by Scanning Electron Microscopy is a maximum of 2 μm.

In one aspect, the invention provides a dry graphene powder composition comprising; pristine graphene flakes, wherein the pristine graphene flakes are non-covalently functionalised with polymeric amphiphilic molecules; and wherein the number of layers of graphene within at least 50% of the pristine graphene flakes as determined by Atomic Force Microscopy is a maximum of 2.

In one aspect, the invention provides a method of preparing the dry graphene powder composition of the invention as defined in any preceding aspect comprising;
a. providing a graphite starting material;
b. optionally, pre-treating the graphite starting material;
c. exfoliating and simultaneously non-covalently functionalising the graphite in the presence of an aqueous solution of polymeric amphiphilic molecules, to provide a dispersion of non-covalently functionalised exfoliated pristine graphene flakes;
d. separating any remaining graphite from the dispersion of non-covalently functionalised exfoliated pristine graphene flakes produced in step c), and;
e. purifying the dispersion of non-covalently functionalised exfoliated pristine graphene flakes produced in step d) to remove any excess polymeric amphiphilic molecules in solution which are not non-covalently attached to the exfoliated pristine graphene flakes;
f. optionally further comprising removing the solvent from the purified dispersion of non-covalently functionalised exfoliated pristine graphene flakes produced in step e), to provide the dry graphene powder composition.

In one aspect, the graphite starting material utilised in the method of preparing the dry graphene powder composition of the invention is natural graphite, or any type of non-oxidised graphite including but not limited to synthetic graphite, expandable graphite, intercalated graphite, electrochemically exfoliated graphite or recycled graphite.

In one aspect, the method of preparing the dry graphene powder composition of the invention comprises a pre-treatment step b), wherein the graphite starting material is pre-treated by alternately soaking the graphite in liquid nitrogen and absolute ethanol to trigger modest expansion of the graphite layers.

In one aspect, the method of preparing the dry graphene powder composition of the invention comprises a pre-treatment step b), wherein the graphite is pre-treated by electrochemically exfoliating graphite to produce graphite particles.

In one aspect, the method of preparing the dry graphene powder composition of the invention comprises a pre-treatment step b), wherein the graphite starting material is pre-treated by alternately soaking the graphite in liquid nitrogen and absolute ethanol to trigger modest expansion of the graphite layers, and then the graphite is electrochemically exfoliated to produce graphite particles.

In one aspect, the method of preparing the dry graphene powder composition of the invention comprises a pre-treatment step b), wherein the graphite is pre-treated by electrochemically exfoliating graphite to produce graphite particles, preferably wherein the electrochemical exfoliation is anodic electrochemical exfoliation, preferably wherein the anodic electrochemical exfoliation is conducted in an aqueous electrolyte, preferably wherein the aqueous electrolyte is aqueous ammonium sulfate, preferably wherein the anodic electrochemical exfoliation is conducted in the presence of an antioxidant, preferably wherein the antioxidant is (2,2,6,6-Tetramethylpiperidin-1-yl)oxyl (TEMPO).

In one aspect, the method of preparing the dry graphene powder composition of the invention comprises an intermediate step wherein the graphite particles produced in the pre-treatment step b) are filtered, washed and dried before step c), preferably wherein filtering, washing and drying the graphite particles comprises filtering and washing alternately with water and ethanol, followed by drying under reduced pressure.

In one aspect, the invention provides the method of preparing the dry graphene powder composition of the invention wherein exfoliating and simultaneously non-covalently functionalising the graphite in the presence of an aqueous solution of polymeric amphiphilic molecules, to provide a dispersion of non-covalently functionalised exfoliated pristine graphene flakes in accordance with step c), is achieved via ultra-sonication, mild-sonication, shear-mixing or vortex-mixing, preferably ultra-sonication, preferably wherein the initial concentration of graphite is within the range of 5 to 20 mg/ml, most preferably 10 mg/ml, preferably wherein the initial concentration of polymeric amphiphilic molecules is within the range of 0.1 to 10 mg/ml, preferably wherein step c) is continued for up to 4 hours.

In one aspect, the method of preparing the dry graphene powder composition of the invention comprises exfoliating and simultaneously non-covalently functionalising the graphite in the presence of an aqueous solution of polymeric amphiphilic molecules wherein, the polymeric amphiphilic molecules are molecules as defined in Formula I.

In one aspect, the invention provides the method of preparing the dry graphene powder composition of the invention wherein separating any remaining graphite from the dispersion of non-covalently functionalised exfoliated pristine graphene flakes in accordance with step d) comprises;
a. mild centrifugation of the dispersion product of step c), preferably at 2000 rpm for 30 minutes, to sediment down any remaining graphite; and
b. decanting the supernatant containing the dispersion of non-covalently functionalised exfoliated pristine graphene flakes for further purification in accordance with step e).

In one aspect, the invention provides the method of preparing the dry graphene powder composition of the invention wherein purifying the dispersion of non-covalently functionalised exfoliated pristine graphene flakes in accordance with step e) comprises:
iii. ultracentrifugation of the product of step d), preferably at 15,000-60,000 rpm for 60 minutes, to sediment down the non-covalently functionalised exfoliated pristine graphene flakes;
iv. decanting the supernatant containing the excess polymeric amphiphilic molecules in solution which are not non-covalently attached to the exfoliated pristine graphene flakes;
v. redispersing the non-covalently functionalised exfoliated pristine graphene flakes in aqueous or alcoholic media, or pure water, preferably via sonication for two minutes; and
vi. preferably repeating steps iii & iv at least once.

In one aspect, the invention provides the method of preparing the dry graphene powder composition of the invention wherein removing the solvent in accordance with step f) to provide the dry graphene powder composition comprises lyophilising the product of step e).

In one aspect, the invention provides a stable homogenous dispersion comprising, pristine graphene flakes in aqueous or alcoholic media wherein the media is free from dispersants or stabilizers.

In one aspect, the invention provides a stable homogenous dispersion comprising the dry graphene powder composition of the invention redispersed in aqueous or alcoholic media, optionally an alcohol/water mixture, preferably pure water.

In one aspect, the invention provides a stable homogenous dispersion comprising, pristine graphene flakes at a concentration of up to 15 mg/ml, preferably at a concentration of 10 mg/ml.

In one aspect, the invention provides a stable homogenous dispersion or a slurry or paste comprising, pristine graphene flakes prepared by the method of the invention wherein step f) of the method has been omitted.

In one aspect, the invention provides a graphene ink for use in 2D or 3D printing comprising, the dry graphene powder of the invention, or the stable homogeneous dispersion of the invention, or the slurry or paste of the invention, preferably wherein the concentration of the graphene in the ink is within the range of 0.1 to 10 mg/ml, preferably wherein the surface tension of the ink is within the range of 60 to 80 mN/m, or 62 to 79 mN/m, or 64 to 78 mN/m, or 66 to 77 mN/m, or 68 to 76 mN/m, or 69 to 75 mN/m, or 70 to 74 mN/m, preferably wherein the viscosity of the ink is within the range of 1.0 to 2.1 mPas.

In one aspect, the invention provides the use of the dry graphene powder of the invention, or the stable homogeneous dispersion of the invention, or the slurry or paste of the invention, or the graphene ink of the invention, to produce one or more 3D or 2D printed articles, including, but not limited to, conductive circuits, electrode materials, electrocatalyst layers/supports, or to produce pristine graphene fibers, or to fabricate a nanocomposite material incorporating pristine graphene.

In one aspect, the invention provides a 3D or 2D printed article, printed using the dry graphene powder of the invention, or the stable homogeneous dispersion of the invention, or the slurry or paste of the invention, or the graphene ink of the invention, preferably wherein the conductivity of the article measured as sheet resistance is better than 350 Ω/sq, more preferably better than 35 Ω/sq, even more preferably approximately 30 Ω/sq, without the need for carrying out thermal annealing.

In one aspect, the invention provides a process for printing a 2D article comprising, printing the stable homogeneous dispersion of the invention, or the slurry or paste of the invention, or the graphene ink of the invention onto a 2D substrate and then drying; optionally wherein the 2D substrate is a flexible substrate and/or wherein the 2D article is a flexible conductive circuit.

In one aspect, the invention provides a process for printing a 3D article comprising, printing the stable homogeneous dispersion of the invention, or the slurry or paste of the invention, or the graphene ink of the invention into a coagulant bath containing a suitable coagulant, followed by removal from the bath, freezing and then drying, preferably wherein the coagulant bath contains 1-10 wt % carboxymethylcellulose sodium salt (CMC) solution as the coagulant, most preferably 5 wt % carboxymethylcellulose sodium salt (CMC) solution as the coagulant, preferably wherein freezing is carried out by immersing the 3D printed article in liquid nitrogen, preferably wherein drying is carried out by lyophilisation.

In one aspect, the invention provides pristine graphene fibers, manufactured from the dry graphene powder of the invention, or the stable homogeneous dispersion of the invention, or the slurry or paste of the invention, or the graphene ink of the invention.

In one aspect, the invention provides a process for wet-spinning pristine graphene fibers comprising, injecting the stable homogeneous dispersion of the invention, or the slurry or paste of the invention, or the graphene ink of the invention preferably a concentrated graphene dispersion (5 mg mL⁻¹) of PTEBS functionalised pristine graphene powder dispersed in aqueous poly(1-vinyl-3-ethylimidazolium bromide) solution (1 wt %), into a coagulant bath containing a suitable coagulant, preferably wherein the coagulant bath contains 1-10 wt % carboxymethylcellulose sodium salt (CMC) solution as the coagulant, most preferably 5 wt % carboxymethylcellulose sodium salt (CMC) solution as the coagulant.

In one aspect, the invention provides a process for fabricating a nanocomposite material incorporating pristine graphene comprising forming a stable homogeneous dispersion including the dry graphene powder of the invention, and a solubilised matrix material, and inducing self-assembly of the pristine graphene with the matrix material, optionally wherein;
a) the matrix material is capable of forming a composite, or hydrogel, or aerogel; and/or
b) the matrix material is a protein, a peptide, a polymer, a biopolymer or an oligomer; and/or
c) the matrix material is silk fibroin; and/or
d) the stable homogeneous dispersion is formed by mixing graphene powder dispersed in aqueous media with an aqueous solution of matrix material; and/or
e) the stable homogeneous dispersion is formed by mixing graphene powder dispersed in water with an aqueous solution of silk fibroin; and/or
f) the stable homogeneous dispersion is formed by mixing graphene powder dispersed in water (at 2 mg/mL) with an aqueous solution of silk fibroin (at 30 wt %); and/or
g) the self-assembly is induced chemically or physically or electrically; and/or
h) the self-assembly is induced chemically by adding a cross-linking agent or adjusting the pH or electrolyte concentration of the homogeneous dispersion; or
i) the self-assembly is induced by evaporating the solvent of the homogeneous dispersion; or
j) the self-assembly is induced physically by sonication; or
k) the self-assembly is induced electrically by applying a DC current; or
l) the self-assembly is induced thermally by heating and/or cooling; or
m) the self-assembly is induced mechanically by shearing.

### BRIEF DESCRIPTION OF THE DRAWINGS

Further features of the present invention are more fully described in the following description of several non-limiting embodiments thereof. This description is included solely for the purposes of exemplifying the present invention. It should not be understood as a restriction on the broad summary, disclosure or description of the invention as set out above. The description will be made with reference to the accompanying drawings in which:

FIG. 1 is a schematic illustration of a method for producing dry graphene powder with redispersibility in water. The method comprises: (a) liquid-phase exfoliation of graphite in the presence of polymeric amphiphilic molecules, which adsorb onto the basal plane of the graphene flakes and impart hydrophilicity; (b) purification of the exfoliated graphene dispersion to remove any unexfoliated graphite and any excess unadsorbed polymeric amphiphilic molecules; and (c) removal of water in the dispersion to produce the dry pristine graphene powder of the invention.

FIG. 2A is a photograph of the dilute aqueous solution of amphiphilic PTEBS molecules (left), the graphene dispersion stabilized by amphiphilic PTEBS molecules before purification (middle), and after purification (right).

FIG. 2B is a UV-Vis absorption spectrum of the dilute aqueous solution of amphiphilic PTEBS molecules (orange trace), the graphene dispersion stabilized by amphiphilic PTEBS molecules before purification (cyan trace), and after purification (blue trace).

FIG. 3 is a plot of the concentration of the stable graphene dispersions of the invention as a function of the concentration of amphiphilic PTEBS molecules.

FIG. 4 is a plot of the graphene concentration and yield, of the stable graphene dispersions of the invention, as a function of the initial graphite concentration. For this data, the initial PTEBS concentration was set at 1 mg mL⁻¹ and the sonication time was 1 h. Graphene concentration was measured while controllably varying the initial graphite concentration from 1 mg mL⁻¹ to 100 mg mL⁻¹.

FIG. 5 is a plot of the graphene concentration of the stable graphene dispersions of the invention, as a function of sonication time. For this data, the initial graphite concentration was set at 10 mg mL⁻¹ and the initial PTEBS concentration was set at 1 mg mL⁻¹. Graphene concentration was measured while varying the sonication time from 30 min to 12 h.

FIG. 6 is a thermogravimetric analysis of the initial PTEBS (orange trace), the starting graphite (red trace), and the as-prepared pristine graphene powder of the invention (blue trace). The mass of PTEBS is estimated to account for ˜2% of the total mass of graphene powder (PTEBS/graphene mass ratio ˜0.02).

FIGS. 7A-C are Transmission Electron Microscopy (TEM) images of the exfoliated pristine graphene flakes of the invention (inset in FIG. 7C: selected-area electron diffraction pattern).

FIG. 7D is a Scanning Electron Microscopy (SEM) image of the pristine graphene flakes of the invention on an alumina membrane.

FIG. 7E is an Atomic Force Microscopy (AFM) image of a single pristine graphene flake of the invention.

FIG. 7F is a plot of the height profile of the sheet, marked by the dashed line in FIG. 7E.

FIG. 8A is a plot of the statistical lateral size distribution of a sample of pristine graphene flakes of the invention, determined by SEM.

FIG. 8B is a plot of the statistical height profile analysis of a sample of pristine graphene flakes of the invention, determined by AFM.

FIG. 9A is a photograph of the dry pristine graphene powder of the invention (left) and the same powder redispersed in water (right).

FIG. 9B is a Raman spectrum of a sample of the dry pristine graphene powder of the invention.

FIG. 9C is an X-Ray Photoelectron Spectroscopy (XPS) survey spectrum of a sample of the dry pristine graphene powder of the invention.

FIG. 9D is a C 1s core level XPS spectrum of a sample of the dry pristine graphene powder of the invention.

FIG. 10 is a photograph of dilute aqueous solutions of PVA (left), amphiphilic PTAA molecules (middle) and amphiphilic PTEBS molecules (right).

FIG. 11 is a photograph of graphene, exfoliated via sonication in each of the dilute aqueous solutions depicted in FIG. 10, PVA (left), amphiphilic PTAA molecules (middle) and amphiphilic PTEBS molecules (right), prior to purification to remove any excess unadsorbed free dispersants or stabilizers.

FIG. 12 is a photograph of graphene, exfoliated via sonication in each of the dilute aqueous solutions depicted in FIG. 10, PVA (left), amphiphilic PTAA molecules (middle) and amphiphilic PTEBS molecules (right), after purification to remove any excess unadsorbed free dispersants or stabilizers.

FIG. 13 is a photograph of the water-redispersible dry pristine graphene powders of the invention, prepared by lyophilisation of the purified dispersions depicted in FIG. 12, with adsorbed amphiphilic PTAA molecules (left) and adsorbed amphiphilic PTEBS molecules (right).

FIG. 14 is a photograph of the water-redispersible dry pristine graphene powders of the invention depicted in FIG. 13, after redispersal in water with adsorbed amphiphilic PTAA molecules (left) and adsorbed amphiphilic PTEBS molecules (right).

FIG. 15 is a series of photographs demonstrating the stability of the stable homogeneous aqueous dispersions of pristine graphene powders of the invention with adsorbed amphiphilic PTAA molecules (left) and adsorbed amphiphilic PTEBS molecules (right), after 30 minutes (top), after 1 hour (middle) and after 1 day (bottom).

FIG. 16A is a diagrammatic representation of the surface tensions of pure water (left), graphene ink of the invention at concentration of 1 mg mL⁻¹ (middle), and graphene ink of the invention at concentration of 10 mg mL⁻¹ (right).

FIG. 16B is a plot of the viscosity of the graphene inks of the invention as a function of graphene concentration.

FIG. 16C is a photograph of a typical printing process of the formulated graphene inks of the invention using a 3D printer, printing onto a glass slide.

FIG. 16D is a photograph of a typical printing process of the formulated graphene inks of the invention using a 3D printer, printing a flexible conductive circuit onto a PET film.

FIG. 16E is a photograph demonstrating the ability of the flexible conductive circuits of the invention to bend without failure.

FIG. 16F is a photograph of light emitting from an LED incorporated into a flexible conductive circuit of the invention, demonstrating ability of the flexible conductive circuits of the invention to continue to operate effectively after bending.

FIG. 17 is a photograph of wet-spinning of pristine graphene fibers of the invention.

FIG. 18A is a photograph of a stable and homogeneous graphene/silk fibroin dispersion, prepared using the water-redispersible dry pristine graphene powder of the invention.

FIG. 18B is a photograph of a conductive graphene, graphene/silk fibroin hydrogel prepared via sonication induced physical cross-linking and self assembly of the stable and homogeneous graphene/silk fibroin dispersion of the invention.

### DEFINITIONS

As used herein, the singular forms “a,” “an” and “the” include plural references unless the context clearly dictates otherwise.

As used herein, “alkyl”, “alkenyl”, “alkynyl”, “alkanediyl”, “alkenediyl” and “alkynediyl” if not specified, contain from 1 to 20 carbons, or 1 to 16 carbons, and are straight or branched carbon chains. Alkenyl and alkanediyl carbon chains are from 2 to 20 carbons, and, in certain embodiments, contain 1 to 8 double bonds. Alkenyl and alkenediyl carbon chains of 1 to 16 carbons, in certain embodiments, contain 1 to 5 double bonds. Alkynyl and alkynediyl carbon chains are from 2 to 20 carbons, and, in one embodiment, contain 1 to 8 triple bonds. Alkynyl and alkynediyl carbon chains of 2 to 16 carbons, in certain embodiments, contain 1 to 5 triple bonds. Exemplary alkyl, alkenyl and alkynyl groups include, but are not limited to, methyl, ethyl, propyl, isopropyl, isobutyl, n-butyl, sec-butyl, tert-butyl, isopentyl, neopentyl, tert-penytyl and isohexyl. The alkyl, alkenyl, alkynyl, alkanediyl, alkenediyl and alkynediyl groups, unless otherwise specified, can be optionally substituted, with one or more groups, including alkyl group substituents that can be the same or different. The alkyl, alkenyl, alkynyl, alkanediyl, alkenediyl and alkynediyl groups as used herein include halogenated alkynyl, alkanediyl, alkenediyl and alkynediyl groups.

As used herein “lower alkyl” designates an alkyl, straight chained or branched, having from about 1-6 carbon atoms, such as methyl, ethyl, propyl, isopropyl, butyl, t-butyl and isobutyl, pentyl, hexyl and isomers thereof.

As used herein, an “alkyl group substituent” includes, but is not limited to, halo, haloalkyl, including halo lower alkyl, aryl, hydroxy, alkoxy, aryloxy, alkyloxy, alkylthio, arylthio, aralkyloxy, aralkylthio, carboxy alkoxycarbonyl, oxo and cycloalkyl.

As used herein, an “aromatic moiety” refers to any aryl group or heteroaryl group.

As used herein, “aryl” refers to aromatic groups containing from 5 to 20 carbon atoms and can be a mono-, multicyclic or fused ring system. Aryl groups include, but are not limited to, phenyl, naphthyl, biphenyl, fluorenyl and others that can be unsubstituted or are substituted with one or more substituents.

As used herein, “aryl” also refers to aryl-containing groups, including, but not limited to, aryloxy, arylthio, arylcarbonyl and arylamino groups.

As used herein, an “aryl group substituent” includes, but is not limited to, alkyl, alkenyl, alkynyl, cycloalkyl, cycloalkylalkyl, aryl, heteroaryl optionally substituted with 1 or more, including 1 to 3, substituents selected from halo, halo alkyl and alkyl, aralkyl, heteroaralkyl, alkenyl containing 1 to 2 double bonds, alkynyl containing 1 to 2 triple bonds, halo, pseudohalo, cyano, hydroxy, haloalkyl and polyhaloalkyl, including halo lower alkyl, especially trifluoromethyl, formyl, alkylcarbonyl, arylcarbonyl that is optionally substituted with 1 or more, including 1 to 3, substituents selected from halo, halo alkyl and alkyl, heteroarylcarbonyl, carboxy, alkoxycarbonyl, aryloxycarbonyl, aminocarbonyl, alkylaminocarbonyl, dialkylaminocarbonyl, arylaminocarbonyl, diarylaminocarbonyl, aralkylaminocarbonyl, alkoxy, aryloxy, perfluoroalkoxy, alkenyloxy, alkynyloxy, arylalkoxy, aminoalkyl, alkylaminoalkyl, dialkylaminoalkyl, arylaminoalkyl, amino, alkylamino, dialkylamino, arylamino, alkylarylamino, alkylcarbonylamino, arylcarbonylamino, azido, nitro, mercapto, alkylthio, arylthio, perfluoroalkylthio, thiocyano, isothiocyano, alkylsulfinyl, alkylsulfonyl, arylsulfinyl, arylsulfonyl, aminosulfonyl, alkylaminosulfonyl, dialkylaminosulfonyl and arylaminosulfonyl.

As used herein, “cycloalkyl” refers to a saturated mono- or multi-cyclic ring system, of 3 to 10 carbon atoms, or 3 to 6 carbon atoms; cycloalkenyl and cycloalkynyl refer to mono- or multicyclic ring systems that respectively include at least one double bond and at least one triple bond. Cycloalkenyl and cycloalkynyl groups can contain, in one embodiment, 3 to 10 carbon atoms, with cycloalkenyl groups, in other embodiments, containing 4 to 7 carbon atoms and cycloalkynyl groups, in other embodiments, containing 8 to 10 carbon atoms. The ring systems of the cycloalkyl, cycloalkenyl and cycloalkynyl groups can be composed of one ring or two or more rings that can be joined together in a fused, bridged or spiro-connected fashion, and can be optionally substituted with one or more alkyl group substituents.

As used herein, “heteroaryl” refers to a monocyclic or multicyclic ring system, of about 5 to about 15 members where one or more, or 1 to 3, of the atoms in the ring system is a heteroatom, which is, an element other than carbon, for example, nitrogen, oxygen and sulfur atoms. The heteroaryl can be optionally substituted with one or more, including 1 to 3, aryl group substituents. The heteroaryl group can be optionally fused to a benzene ring. Exemplary heteroaryl groups include, but are not limited to, pyrroles, porphyrines, furans, thiophenes, selenophenes, pyrazoles, imidazoles, triazoles, tetrazoles, oxazoles, oxadiazoles, thiazoles, thiadiazoles, indoles, carbazoles, benzofurans, benzothiophenes, indazoles, benzimidazoles, benzotriazoles, benzoxatriazoles, benzothiazoles, benzoselenozoles, benzothiadiazoles, benzoselenadiazoles, purines, pyridines, pyridazines, pyrimidines, pyrazines, pyrazines, triazines, quinolines, acridines, isoquinolines, cinnolines, phthalazines, quinazolines, quinoxalines, phenazines, phenanthrolines, imidazinyl, pyrrolidinyl, pyrimidinyl, tetrazolyl, thienyl, pyridyl, pyrrolyl, N-methylpyrrolyl, quinolinyl and isoquinolinyl.

As used herein, “heteroaryl” also refers to heteroaryl-containing groups, including, but not limited to, heteroaryloxy, heteroarylthio, heteroarylcarbonyl and heteroarylamino.

As used herein, “heterocyclic” refers to a monocyclic or multicyclic ring system, in one embodiment of 3 to 10 members, in another embodiment 4 to 7 members, including 5 to 6 members, where one or more, including 1 to 3 of the atoms in the ring system is a heteroatom, which is, an element other than carbon, for example, nitrogen, oxygen and sulfur atoms. The heterocycle can be optionally substituted with one or more, or 1 to 3 aryl group substituents. In certain embodiments, substituents of the heterocyclic group include hydroxy, amino, alkoxy containing 1 to 4 carbon atoms, halo lower alkyl, including trihalomethyl, such as trifluoromethyl, and halogen. As used herein, the term heterocycle can include reference to heteroaryl.

As used herein, the nomenclature alkyl, alkoxy, carbonyl, etc., are used as is generally understood by those of skill in this art. For example, as used herein alkyl refers to saturated carbon chains that contain one or more carbons; the chains can be straight or branched or include cyclic portions or be cyclic.

Where the number of any given substituent is not specified (e.g., “haloalkyl”), there can be one or more substituents present. For example, “haloalkyl” can include one or more of the same or different halogens. As used herein, “halogen” or “halide” refers to F, Cl, Br or I.

As used herein, “haloalkyl” refers to a lower alkyl radical in that one or more of the hydrogen atoms are replaced by halogen including, but not limited to, chloromethyl, trifluoromethyl, 1-chloro-2-fluoroethyl and the like.

As used herein, the terms “heteroalkane”, “heteroalkanediyl”, “heteroalkene”, “heteroalkenediyl”, “heteroalkyne” and “heteroalkynediyl” refer to a compounds or groups derived from the corresponding alkane, alkene or alkyne and comprising at least one “heteroatom” interrupting the main chain, i.e., a non-carbon/non-hydrogen atom such as 0, N or S.

Throughout this specification, unless the context requires otherwise, the word “comprise” or variations such as “comprises” or “comprising”, will be understood to imply the inclusion of a stated integer or group of integers but not the exclusion of any other integer or group of integers.

As used herein, the term “dispersants” or the term “stabilizers” are interchangeable terms which refer to molecules which stabilize a graphene dispersion and thereby prevent or inhibit aggregation of the graphene. Examples of dispersants or stabilizers falling within the definition used herein include surfactants and soluble polymers as well as solvents other than water or alcohols, such as N-methyl pyrrolidone (NMP), dimethylsulfoxide (DMSO) and dimethylformamide (DMF).

As used herein, the term “free dispersants” or the term “free stabilizers” are interchangeable terms which refer to dispersant or stabilizer molecules that are not adsorbed onto the basal plane of graphene, and/or dispersant or stabilizer molecules that are in solution and are not non-covalently bound to graphene.

As used herein, “pristine graphene” refers to graphene having an intact, undamaged basal plane and/or graphene which has been derived from graphite without the involvement of an oxidation and/or reduction process. For example, reduced graphene oxide (rGO) does not fall within the definition of pristine graphene as used herein.

Other than in the operating examples, or where otherwise indicated, all numbers expressing quantities of ingredients, components reaction conditions, and so forth used in the specification and claims are to be understood as being modified in all instances by the term “about”. Accordingly, unless indicated to the contrary, the numerical parameters set forth in the specification and claims are approximations that may vary depending upon the desired properties sought to be obtained by the present invention. Hence “about 80%” means “about 80%” and also “80%”. At the very least, each numerical parameter should be construed in light of the number of significant digits and ordinary rounding approaches.

Notwithstanding that the numerical ranges and parameters setting forth the broad scope of the invention are approximations, the numerical values set forth in the specific examples are reported as precisely as possible. Any numerical value; however, inherently contains certain errors necessarily resulting from the standard deviation found in their respective testing measurements.

The invention described herein may include one or more range(s) of values (eg. concentration, conductivity, viscosity, rpm, time, percent, integers, etc). A range of values will be understood to include all values within the range, including the values defining the range, and values adjacent to the range which lead to the same or substantially the same outcome as the values immediately adjacent to that value which defines the boundary to the range.

A range of values will also be understood to include all sub-ranges of values within the range.

Each document, reference, patent application or patent cited in this text is expressly incorporated herein in their entirety by reference, which means that it should be read and considered by the reader as part of this text. That the document, reference, patent application or patent cited in this text is not repeated in this text is merely for reasons of conciseness.

Any manufacturer's instructions, descriptions, product specifications, and product sheets for any products mentioned herein or in any document incorporated by reference herein, are hereby incorporated herein by reference, and may be employed in the practice of the invention.

The present invention is not to be limited in scope by any of the specific embodiments described herein. These embodiments are intended for the purpose of exemplification only. Functionally equivalent products, formulations and methods are clearly within the scope of the invention as described herein.

Other definitions for selected terms used herein may be found within the detailed description of the invention and apply throughout. Unless otherwise defined, all other scientific and technical terms used herein have the same meaning as commonly understood to one of ordinary skill in the art to which the invention belongs.

### DETAILED DESCRIPTION OF THE INVENTION

### Stable Redispersible Pristine Dry Graphene Powder Compositions

The production of stable redispersible graphene powders, capable of redispersal in aqueous or alcoholic media, is a highly desirable goal for its practical applications. In this specification, we describe the stabilizing effect of non-covalent functionalization during exfoliation of graphene in aqueous or alcoholic media. We demonstrate that the adsorption and non-covalent functionalization of polymeric amphiphilic molecules having an aromatic moiety at one end and a polar moiety at the other end, onto the surface of graphite has the ability to disrupt the π-π interactions holding the graphitic layers stacked together, thereby promoting exfoliation and stabilizing the graphene thus produced against aggregation, even after the removal of solvent. The exfoliated graphene flakes and dry pristine graphene powder of the invention can be redispersed in aqueous or alcoholic media at surprisingly very low dispersant/graphene mass ratios (˜0.02), forming homogeneous dispersions with high stability.

Without wishing to be bound by theory, it is thought that the excellent performance of the polymeric amphiphilic molecules on stabilization of the graphene can be attributed to the synergic effect of π-π stacking interactions of the aromatic moiety of the polymeric amphiphilic molecules, non-covalently attaching itself to the basal plane of the graphene surface and the polar moiety at the opposite end of the polymeric amphiphilic molecules, which confers hydrophilicity on the exfoliated graphene.

It has been surprisingly found that under assistance of exfoliation, polymeric amphiphilic molecules having an aromatic moiety at one end, and a polar moiety at the opposite end can disrupt the π-π interactions via noncovalent functionalisation of the aromatic moiety and strong adsorption onto graphene basal plane, meanwhile the appended polar moiety extends from the exfoliated flakes into the polar aqueous or alcoholic phase to form a stable homogenous dispersion of graphene. As the stabilized-graphene flakes can be solvated in water or alcohol in the absence of free unadsorbed stabilizer or dispersant molecules, the un-adsorbed polymeric amphiphilic molecules can be removed without affecting the stability of the graphene dispersions. Exfoliation and stabilization of graphene via this approach allows for the emergence of a new class of redispersible pristine graphene and provides opportunities for further processing to dry water-redispersible graphene powder.

A stable redispersible pristine dry graphene powder based on non-covalent functionalization via π-π stacking of polymeric amphiphilic molecules to graphene is thereby produced, which shows unprecedented capabilities to formulate stable and concentrated graphene aqueous or alcoholic dispersions, and graphene inks for 2D or 3D printing, with excellent wet-spinnability to pristine graphene fibers.

In one embodiment, the invention provides a dry graphene powder composition comprising; pristine graphene flakes, wherein the pristine graphene flakes are non-covalently functionalised with polymeric amphiphilic molecules; and wherein the dry graphene powder composition is capable of forming a stable homogeneous dispersion in aqueous or alcoholic media, in the absence of free dispersants or stabilizers.

In one embodiment, the invention provides a dry graphene powder composition comprising; pristine graphene flakes, wherein the pristine graphene flakes are non-covalently functionalised with polymeric amphiphilic molecules; and wherein the dry graphene powder composition is capable of forming a stable homogeneous dispersion in an alcohol/water mixture.

In one embodiment, the invention provides a dry graphene powder composition comprising; pristine graphene flakes, wherein the pristine graphene flakes are non-covalently functionalised with polymeric amphiphilic molecules; and wherein the dry graphene powder composition is capable of forming a stable homogeneous dispersion in pure water.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules comprise a terminal aromatic moiety or conjugated double-bond moiety for non-covalently functionalising the pristine graphene flakes via π-π stacking adsorption thereto.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules comprise a terminal and optionally ionisable polar moiety for imparting hydrophilicity to the pristine graphene flakes.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules with a molecular weight within the range of 5 to 100 KDa, or any sub-range falling within the range of 5 to 100 KDa.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I;

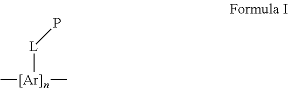

wherein;
Ar is an aromatic moiety;
P is an optionally ionisable polar moiety or a salt thereof;
n is an integer of between 20 and 350;
L is a linker independently selected from the group consisting of; a bond, C₁₋₂₀alkanediyl, C₁₋₂₀heteroalkanediyl, C₁₋₂₀alkenediyl, C₁₋₂₀heteroalkenediyl, C₁₋₂₀alkynediyl, and C₁₋₂₀heteroalkynediyl.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein Ar is a substituted or unsubstituted aromatic moiety independently selected from the group consisting of; thienyl, phenyl, biphenyl, naphthyl, indanyl, indenyl, fluorenyl, pyrenyl, pyridyl, pyrazinyl, pyrimidinyl, pyrrolyl, pyrazolyl, imidazolyl, thiazolyl, oxazolyl, isooxazolyl, thiadiazolyl, triazolyl, oxadiazolyl, thiophenyl, furanyl, quinolinyl, indolyl, and isoquinolinyl moieties.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein P is a polar moiety independently selected from the group consisting of; sulfonate, carboxylate, nitrate, sulfate, carboxamide, amine, substituted amine, quaternary amine, hydroxy, alkyloxy, sulphide, thiol, nitro, and nitrile moieties.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein Ar is thienyl.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein P is sulfonate, carboxylate or salts thereof.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein L is —C₁₋₈alkyl—O—C₁₋₈alkyl—, or —C₁₋₈alkyl-.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein L is −2-ethyloxy-4-butyl-, or methylene.

Poly[2-(3-thienyl)ethyloxy-4-butylsulfonate] sodium salt (PTEBS), a polythiophene derivative, is widely used as an efficient photo-induced charge transfer for polymer photovoltaic applications. PTEBS is a polymeric amphiphilic molecule composed of heterocyclic aromatic rings (thiophene groups) and appended sodium sulfonated functional groups. These sodium sulfonated moieties make PTEBS soluble in water or alcohol while the thiophene groups enable it to interact with graphene, allowing for PTEBS to act as a stabilizer in aqueous solution.

Similarly, poly-(3-thiophene acetic acid) (PTAA), also a polythiophene derivative, is a polymeric amphiphilic molecule composed of heterocyclic aromatic rings (thiophene groups) and appended acetic acid functional groups. These acetic acid moieties also make PTAA soluble in water or alcohol while the thiophene groups enable it to interact with graphene, allowing for PTAA to act as a stabilizer in aqueous solution.

It has been surprisingly found that under assistance of exfoliation, PTEBS or PTAA can disrupt the π-π interactions, and strongly adsorb onto graphene basal plane, meanwhile the appended sodium sulfonated functional groups of PTEBS or the acetic acid functional groups of PTAA extend from the exfoliated flakes into the polar aqueous or alcoholic phase to form a stable homogenous dispersion of graphene. As the stabilized-graphene flakes can be solvated in water or alcohol in the absence of free unadsorbed stabilizer or dispersant molecules, the un-adsorbed PTEBS or PTAA molecules can be removed without affecting the stability of the graphene dispersions.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules are molecules in accordance with Formula I and wherein the compound of Formula I is poly-[2-(3-thienyl)ethyloxy-4-butylsulfonate] sodium salt (PTEBS), or poly-(3-thiophene acetic acid) (PTAA).

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules comprise less than 50% by weight of the composition.

In one embodiment, the invention provides a dry graphene powder composition comprising; pristine graphene flakes, wherein the pristine graphene flakes are non-covalently functionalised with polymeric amphiphilic molecules; and wherein the polymeric amphiphilic molecules comprise approximately 2% by weight of the composition.

In one embodiment, the invention provides a dry graphene powder composition comprising; pristine graphene flakes, wherein the pristine graphene flakes are non-covalently functionalised with polymeric amphiphilic molecules; and wherein the conductivity measured as sheet resistance of a dried thin film prepared therefrom is better than 350 Ω/sq.

In one embodiment, the invention provides a dry graphene powder composition comprising; pristine graphene flakes, wherein the pristine graphene flakes are non-covalently functionalised with polymeric amphiphilic molecules; and wherein the conductivity measured as sheet resistance of a dried thin film prepared therefrom is better than 35 Ω/sq.

In one embodiment, the invention provides a dry graphene powder composition comprising; pristine graphene flakes, wherein the pristine graphene flakes are non-covalently functionalised with polymeric amphiphilic molecules; and wherein the conductivity measured as sheet resistance of a dried thin film prepared therefrom is approximately 30 Ω/sq.

In one embodiment, the invention provides a dry graphene powder composition comprising; pristine graphene flakes, wherein the pristine graphene flakes are non-covalently functionalised with polymeric amphiphilic molecules; and wherein the pristine graphene flakes have a height profile as determined by Atomic Force Microscopy of approximately 1 nm.

In one embodiment, the invention provides a dry graphene powder composition comprising; pristine graphene flakes, wherein the pristine graphene flakes are non-covalently functionalised with polymeric amphiphilic molecules; and wherein the lateral size of at least 50% of the pristine graphene flakes as determined by Scanning Electron Microscopy is a maximum of 2 μm.

In one embodiment, the invention provides a dry graphene powder composition comprising; pristine graphene flakes, wherein the pristine graphene flakes are non-covalently functionalised with polymeric amphiphilic molecules; and wherein the number of layers of graphene within at least 50% of the pristine graphene flakes as determined by Atomic Force Microscopy is a maximum of 2.

### Methods for the Preparation of the Redispersible Dry Graphene Powder Composition

For preparing the dry graphene powder composition of the invention, any source of graphite may be used, including natural graphite, or any type of non-oxidised graphite including but not limited to synthetic graphite, expandable graphite, intercalated graphite, electrochemically exfoliated graphite or recycled graphite.

In one embodiment, the invention provides a method of preparing the dry graphene powder composition of the invention as defined in any preceding aspect comprising;
a. providing a graphite starting material;
b. optionally, pre-treating the graphite starting material;
c. exfoliating and simultaneously non-covalently functionalising the graphite in the presence of an aqueous solution of polymeric amphiphilic molecules, to provide a dispersion of non-covalently functionalised exfoliated pristine graphene flakes;
d. separating any remaining graphite from the dispersion of non-covalently functionalised exfoliated pristine graphene flakes produced in step c), and;
e. purifying the dispersion of non-covalently functionalised exfoliated pristine graphene flakes produced in step d) to remove any excess polymeric amphiphilic molecules in solution which are not non-covalently attached to the exfoliated pristine graphene flakes;
f. optionally further comprising removing the solvent from the purified dispersion of non-covalently functionalised exfoliated pristine graphene flakes produced in step e), to provide the dry graphene powder composition.

In one embodiment, the graphite starting material utilised in the method of preparing the dry graphene powder composition of the invention is natural graphite, or any type of non-oxidised graphite including but not limited to synthetic graphite, expandable graphite, intercalated graphite, electrochemically exfoliated graphite or recycled graphite.

A particularly useful starting material is pre-treated graphite which has been subjected to a pre-treatment via electrochemical exfoliation. Electrochemically exfoliated graphite can be easily extracted into high quality individual graphene sheets and can be mass produced in a cost-effective manner [23]. The basic principle behind the electrochemical exfoliation process is based on the expansion and subsequent delamination of graphite electrodes triggered by bubble evolution or ion intercalation under a direct current voltage in an ionically conductive solution (such as an electrolyte) [24,25]. Anodic electrochemical exfoliation of graphite can be readily accomplished in aqueous medium in very short times (even minutes) and has a lower environmental impact than the cathodic approach, which usually involve lithium-, sodium-, alkylammonium- or imidazolium-based salts in organic solvents [26,27]. The use of an aqueous electrolyte, therefore, is more cost-effective and desirable from a practical processing standpoint [28]. However, the anodic process is carried out with graphite under oxidizing conditions (at the positive electrode), which can compromise the quality of the resulting graphene [29,30]. Therefore, to avoid the oxidative attack of hydroxyl and other oxygen radicals generated from water electrolysis during the anodic process, an antioxidant such as (2,2,6,6-Tetramethylpiperidin-1-yl)oxyl (TEMPO) may be used for eliminating the highly reactive oxygen radicals at the graphite anode, thereby inhibiting the oxidation of the carbon lattice for the production of pristine graphene nanosheets with low defects and good electrical conductivity [23,31].

In one embodiment, the method of preparing the dry graphene powder composition of the invention comprises a pre-treatment step b), wherein the graphite starting material is pre-treated by alternately soaking the graphite in liquid nitrogen and absolute ethanol to trigger modest expansion of the graphite layers.

In one embodiment, the method of preparing the dry graphene powder composition of the invention comprises a pre-treatment step b), wherein the graphite is pre-treated by electrochemically exfoliating graphite to produce graphite particles.

In one embodiment, the method of preparing the dry graphene powder composition of the invention comprises a pre-treatment step b), wherein the graphite starting material is pre-treated by alternately soaking the graphite in liquid nitrogen and absolute ethanol to trigger modest expansion of the graphite layers, and then the graphite is electrochemically exfoliated to produce graphite particles.

In one embodiment, the method of preparing the dry graphene powder composition of the invention comprises a pre-treatment step b), wherein the graphite is pre-treated by electrochemically exfoliating graphite to produce graphite particles, preferably wherein the electrochemical exfoliation is anodic electrochemical exfoliation, preferably wherein the anodic electrochemical exfoliation is conducted in an aqueous electrolyte, preferably wherein the aqueous electrolyte is aqueous ammonium sulfate, preferably wherein the anodic electrochemical exfoliation is conducted in the presence of an antioxidant, preferably wherein the antioxidant is (2,2,6,6-Tetramethylpiperidin-1-yl)oxyl (TEMPO).

In one embodiment, the method of preparing the dry graphene powder composition of the invention comprises an intermediate step wherein the graphite particles produced in the pre-treatment step b) are filtered, washed and dried before step c), preferably wherein filtering, washing and drying the graphite particles comprises filtering and washing alternately with water and ethanol, followed by drying under reduced pressure.

In one embodiment, the invention provides the method of preparing the dry graphene powder composition of the invention wherein exfoliating and simultaneously non-covalently functionalising the graphite in the presence of an aqueous solution of polymeric amphiphilic molecules, to provide a dispersion of non-covalently functionalised exfoliated pristine graphene flakes in accordance with step c), is achieved via ultra-sonication, mild-sonication, shear-mixing or vortex-mixing, preferably ultra-sonication, preferably wherein the initial concentration of graphite is within the range of 5 to 20 mg/ml, most preferably 10 mg/ml, preferably wherein the initial concentration of polymeric amphiphilic molecules is within the range of 0.1 to 10 mg/ml, preferably wherein step c) is continued for up to 4 hours.

In one embodiment, the method of preparing the dry graphene powder composition of the invention comprises exfoliating and simultaneously non-covalently functionalising the graphite in the presence of an aqueous solution of polymeric amphiphilic molecules wherein, the polymeric amphiphilic molecules are molecules as defined in Formula I.

In one embodiment, the invention provides the method of preparing the dry graphene powder composition of the invention wherein separating any remaining graphite from the dispersion of non-covalently functionalised exfoliated pristine graphene flakes in accordance with step d) comprises;
i. mild centrifugation of the dispersion product of step c), preferably at 2000 rpm for 30 minutes, to sediment down any remaining graphite; and
ii. decanting the supernatant containing the dispersion of non-covalently functionalised exfoliated pristine graphene flakes for further purification in accordance with step e).

In one embodiment, the invention provides the method of preparing the dry graphene powder composition of the invention wherein purifying the dispersion of non-covalently functionalised exfoliated pristine graphene flakes in accordance with step e) comprises:
iii. ultracentifugation of the product of step d), preferably at 15,000-60,000 rpm for 60 minutes, to sediment down the non-covalently functionalised exfoliated pristine graphene flakes;
iv. decanting the supernatant containing the excess polymeric amphiphilic molecules in solution which are not non-covalently attached to the exfoliated pristine graphene flakes;
v. redispersing the non-covalently functionalised exfoliated pristine graphene flakes in aqueous or alcoholic media, or pure water, preferably via sonication for two minutes; and
vi. preferably repeating steps iii & iv at least once.

In one embodiment, the invention provides the method of preparing the dry graphene powder composition of the invention wherein removing the solvent in accordance with step f) to provide the dry graphene powder composition comprises lyophilising the product of step e).

### Stable Homogeneous Dispersions of Pristine Graphene in Aqueous or Alcoholic Media

In one embodiment, the invention provides a stable homogenous dispersion comprising, pristine graphene flakes in aqueous or alcoholic media wherein the media is free from dispersants or stabilizers.

In one embodiment, the invention provides a stable homogenous dispersion comprising the dry graphene powder composition of the invention redispersed in aqueous or alcoholic media, optionally an alcohol/water mixture, preferably pure water.

In one embodiment, the invention provides a stable homogenous dispersion comprising, pristine graphene flakes at a concentration of up to 15 mg/ml, preferably at a concentration of 10 mg/ml.

In one embodiment, the invention provides a stable homogenous dispersion or a slurry or paste comprising, pristine graphene flakes prepared by the method of the invention wherein step f) of the method has been omitted.

### Graphene Inks

In one embodiment, the invention provides a graphene ink for use in 2D or 3D printing comprising, the dry graphene powder of the invention, or the stable homogeneous dispersion of the invention, or the slurry or paste of the invention, preferably wherein the concentration of the graphene in the ink is within the range of 0.1 to 10 mg/ml, preferably wherein the surface tension of the ink is within the range of 60 to 80 mN/m, or 62 to 79 mN/m, or 64 to 78 mN/m, or 66 to 77 mN/m, or 68 to 76 mN/m, or 69 to 75 mN/m, or 70 to 74 mN/m, preferably wherein the viscosity of the ink is within the range of 1.0 to 2.1 mPas.

### 3D and 2D Printing

In one embodiment, the invention provides the use of the dry graphene powder of the invention, or the stable homogeneous dispersion of the invention, or the slurry or paste of the invention, or the graphene ink of the invention, to produce one or more 3D or 2D printed articles, including, but not limited to, conductive circuits, electrode materials, electrocatalyst layers/supports or to produce pristine graphene fibers, or to fabricate a nanocomposite material incorporating pristine graphene.

In one embodiment, the invention provides a 3D or 2D printed article, printed using the dry graphene powder of the invention, or the stable homogeneous dispersion of the invention, or the slurry or paste of the invention, or the graphene ink of the invention, preferably wherein the conductivity of the article measured as sheet resistance is better than 350 Ω/sq, more preferably better than 35 Ω/sq, even more preferably approximately 30 Ω/sq, without the need for carrying out thermal annealing.

In one embodiment, the invention provides a process for printing a 2D article comprising, printing the stable homogeneous dispersion of the invention, or the slurry or paste of the invention, or the graphene ink of the invention onto a 2D substrate and then drying; optionally wherein the 2D substrate is a flexible substrate and/or wherein the 2D article is a flexible conductive circuit.

In one embodiment, the invention provides a process for printing a 3D article comprising, printing the stable homogeneous dispersion of the invention, or the slurry or paste of the invention, or the graphene ink of the invention into a coagulant bath containing a suitable coagulant, followed by removal from the bath, freezing and then drying, preferably wherein the coagulant bath contains 1-10 wt % carboxymethylcellulose sodium salt (CMC) solution as the coagulant, most preferably 5 wt % carboxymethylcellulose sodium salt (CMC) solution as the coagulant, preferably wherein freezing is carried out by immersing the 3D printed article in liquid nitrogen, preferably wherein drying is carried out by lyophilisation.

### Pristine Graphene Fibers

In one embodiment, the invention provides pristine graphene fibers, manufactured from the dry graphene powder of the invention, or the stable homogeneous dispersion of the invention, or the slurry or paste of the invention, or the graphene ink of the invention.

In one embodiment, the invention provides a process for wet-spinning pristine graphene fibers comprising, injecting the stable homogeneous dispersion of the invention, or the slurry or paste of the invention, or the graphene ink of the invention, preferably a concentrated graphene dispersion (5 mg mL⁻¹) of PTEBS functionalised pristine graphene powder dispersed in aqueous poly(1-vinyl-3-ethylimidazolium bromide) solution (1 wt %), into a coagulant bath containing a suitable coagulant, preferably wherein the coagulant bath contains 1-10 wt % carboxymethylcellulose sodium salt (CMC) solution as the coagulant, most preferably 5 wt % carboxymethylcellulose sodium salt (CMC) solution as the coagulant.

Nanocomposites

In one embodiment, the invention provides the use of the dry graphene powder of the invention, or the stable homogeneous dispersion of the invention, or the slurry or paste of the invention, or the graphene ink of the invention, to fabricate a nanocomposite material incorporating pristine graphene.

In one embodiment, the invention provides a process for fabricating a nanocomposite material incorporating pristine graphene comprising forming a stable homogeneous dispersion including the dry graphene powder of the invention, and a solubilised matrix material, and inducing self-assembly of the pristine graphene with the matrix material, optionally wherein;
a) the matrix material is capable of forming a composite, or hydrogel, or aerogel; and/or
b) the matrix material is a protein, a peptide, a polymer, a biopolymer or an oligomer; and/or
c) the matrix material is silk fibroin; and/or
d) the stable homogeneous dispersion is formed by mixing graphene powder dispersed in aqueous media with an aqueous solution of matrix material; and/or
e) the stable homogeneous dispersion is formed by mixing graphene powder dispersed in water with an aqueous solution of silk fibroin; and/or
f) the stable homogeneous dispersion is formed by mixing graphene powder dispersed in water (at 2 mg/mL) with an aqueous solution of silk fibroin (at 30 wt %); and/or
g) the self-assembly is induced chemically or physically or electrically; and/or
h) the self-assembly is induced chemically by adding a cross-linking agent or adjusting the pH or electrolyte concentration of the homogeneous dispersion; or
i) the self-assembly is induced by evaporating the solvent of the homogeneous dispersion; or
j) the self-assembly is induced physically by sonication; or
k) the self-assembly is induced electrically by applying a DC current; or
l) the self-assembly is induced thermally by heating and/or cooling; or
m) the self-assembly is induced mechanically by shearing.

The present inventors have herein described and demonstrated the production of stable and redispersible pristine graphene powder via π-π stacking interactions utilizing polymeric amphiphilic molecules. Significantly, the pristine graphene powder described herein is high quality, free of defects, and can be redispersed in the aqueous or alcoholic phase without the presence of free, unadsorbed dispersants or stabilizers. The redispersible pristine graphene can be used for formulation of conductive inks and printed using a 2D or 3D printer, resulting in graphene circuits including flexible conductive circuits possessing high resilience to deformation without circuit failure, and microlattices suitable for use as electrocatalyst supports, with superior conductivity of ˜30 Ω/sq. The inventors have also described and demonstrated, to the best of their knowledge for the very first time, the fabrication of pristine graphene fibers, and have demonstrated the incorporation of pristine graphene into biocompatible nanocomposite materials. The described redispersible pristine graphene powder can be mass-produced on an industrially accessible scale and shows great potential in a wide range of applications.

The following examples serve to more fully describe the manner of using the above-described invention, as well as to set forth the best modes contemplated for carrying out various aspects of the invention. It is understood that these methods in no way serve to limit the true scope of this invention, but rather are presented for illustrative purposes.

### EXAMPLES

### Example 1—Electrochemical Exfoliation of Graphite (Pre-Treatment)

Unless otherwise stated, all chemicals were purchased from Sigma-Aldrich™ (Australia) and used as received. The exfoliation of graphite was carried out electrochemically in a two-electrode system using an anodic approach, where a graphite electrode was used as the anode and a platinum electrode was used as the cathode [23].

High purity graphite rods (99.995% trace metals basis, 3 mm diameter and 150 mm length) were pre-treated by alternately soaking in liquid nitrogen and absolute ethanol to trigger modest expansion of the graphite layers. After being dried in an oven, the graphite rod was placed parallel to the platinum electrode with a fixed distance of 4 cm and connected to the power source. As electrolyte, 200 mg of TEMPO (2,2,6,6-tetramethyl-1-piperidinyloxy) was dissolved in 200 mL of 0.05 M (NH₄)₂SO₄ (ammonium sulfate) aqueous solution. Both electrodes were immersed in the electrolyte with 10 cm effective length exposed to the solution. A positive voltage of 10 V was applied to the graphite anode to start the electrochemical exfoliation process using an Instek™ GPR-6030D power supply. During this process, gas bubbles were formed at both electrodes, with the graphite anode gradually expanding and releasing graphitic fragment particles from its surface. When the exfoliation was completed, the product was filtered and washed alternatively with water and ethanol.

The final solid materials were dried under vacuum overnight, resulting in electrochemically exfoliated graphite particles with increased space between graphitic layers, and suitable as a starting material for the preparation of the redispersible dry graphene powder composition of the invention.

### Example 2—Preparation of Redispersible, Dry, Pristine Graphene Powder

Poly[2-(3-thienyl)ethyloxy-4-butylsulfonate] sodium salt (PTEBS), M_{w}=40-70 KDa was obtained from Solaris Chem™ (Canada) and used as provided. Poly-(3-thiophene acetic acid) (PTAA), M_{w}=6.5 KDa, was prepared according to the method of Aydin et al [52]. The preparation of PTEBS- and PTAA-non-covalently functionalised graphene dispersions involved ultrasonication of the previously prepared electrochemically exfoliated graphite of example 1 in aqueous PTEBS and PTAA solution at different experimental parameters.

In a typical experiment, 100 mg of the graphite powder was added to 10 mL of 1 mg mL⁻¹ PTEBS or PTAA solution and ultrasonicated for 30 min. For the PTAA solution, pH of the solution was adjusted to pH=12 in order to ionize the terminal acetic acid group, prior to the addition of the graphite powder. The resulting dispersion was centrifuged at 2000 rpm for 30 min to remove any remaining graphite starting material, and the supernatant was collected for further purification. The resulting supernatant was a stable black colour, indicating the successful exfoliation and stabilization of graphene.

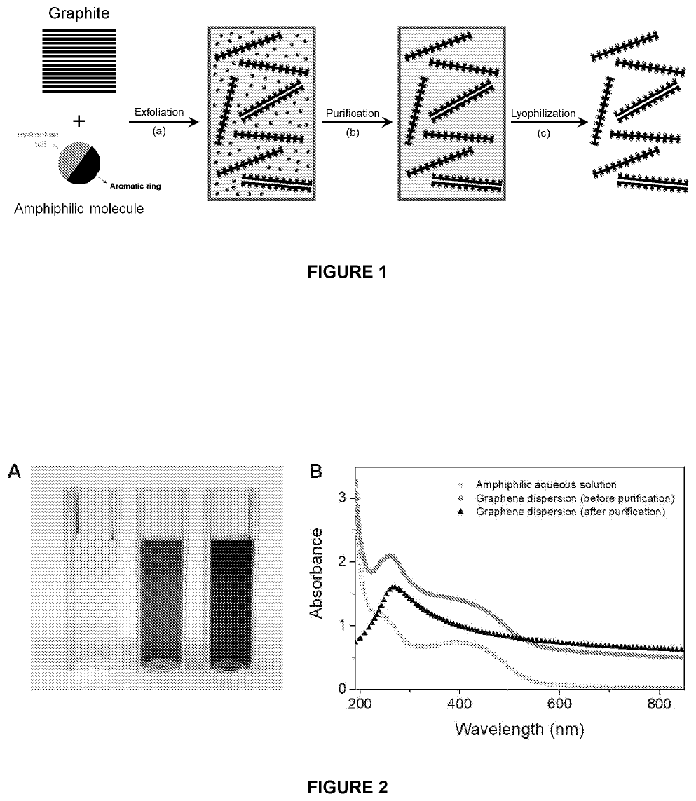

To remove excess unadsorbed PTEBS or PTAA from the graphene dispersion, the suspension was subjected to two cycles of purification by ultracentrifugation at 15000 rpm for 60 min to sediment down the graphene flakes, and redispersion in pure water by sonication for 2 min yielding stable graphene dispersions without the presence of excess unadsorbed dispersant in the solutions. The preparation process of PTEBS and PTAA functionalized pristine graphene aqueous dispersions is illustrated in FIG. 1. The purified graphene suspensions were finally lyophilized to yield light weight, redispersible dry graphene powders.

To give more insight into the presence of PTEBS molecules in the stabilized graphene dispersions, we sought to compare the difference between the graphene suspensions before, and after purification. FIG. 2A shows the photograph of the aqueous PTEBS solution (left cuvette), graphene dispersion before purification (middle cuvette), and after purification (right cuvette). A unique orange color was observed in the aqueous PTEBS solution, which was still apparent in the graphene dispersion before purification. In contrast, graphene dispersion after purification showed a pristine black color without the presence of the orange shade, suggesting the absence of PTEBS molecules. The corresponding UV-vis absorption spectrums of these three cuvettes are shown in FIG. 2B. The orange trace represents the absorption spectrum of the aqueous PTEBS solution, which is dominated by strong adsorption bands in the 200-550 nm wavelength range, with a distinctive peak at 200 nm. The absorption spectrum of the graphene dispersion before purification (cyan trace) exhibited significant absorbance at ˜270 nm and the wavelength above 550 nm, indicating the presence of graphitic carbon [20,33], while the absorption bands characteristic of PTEBS were still apparent. In contrast, the absorption spectrum of the graphene dispersion after purification (blue trace) showed a single band at ˜270 nm, indicative of the π-π*conjugation or non-covalent attachment of the PTEBS to the graphene flakes [20,34,35]. The signature bands of PTEBS were completely gone, indicating the complete removal of free, unadsorbed PTEBS molecules after the sedimentation-redispersion purification process.

The purified graphene dispersions were stable for more than two months without notable precipitation. These results suggest that excess, free or unadsorbed PTEBS or PTAA molecules in solution are not actually required to stabilize the exfoliated graphene sheets in the aqueous dispersions, unlike prior art stabilizers reported in the literature [10,36-40]. Only a relatively small amount of PTEBS or PTAA molecules remained in the dispersions, strongly adsorbed onto the basal plane of the exfoliated graphene sheets, and extending into the solvent phase to stabilize the suspensions.

A set of graphene dispersions using varying experimental parameters were prepared to evaluate the yield of graphene produced. Graphene concentration was estimated according to the classic Lambert-Beer law by measuring the absorbance of the dispersions [14,16]. The initial graphite concentration was set at 10 mg mL⁻¹, which was found to be optimal for the exfoliation of this material in the presence of PTEBS as the polymeric amphiphilic molecule. Lower initial graphite concentrations resulted in correspondingly lower concentrations of graphene, while higher initial graphite concentrations did not yield equally higher concentrations of exfoliated graphene in the dispersions (FIG. 4).

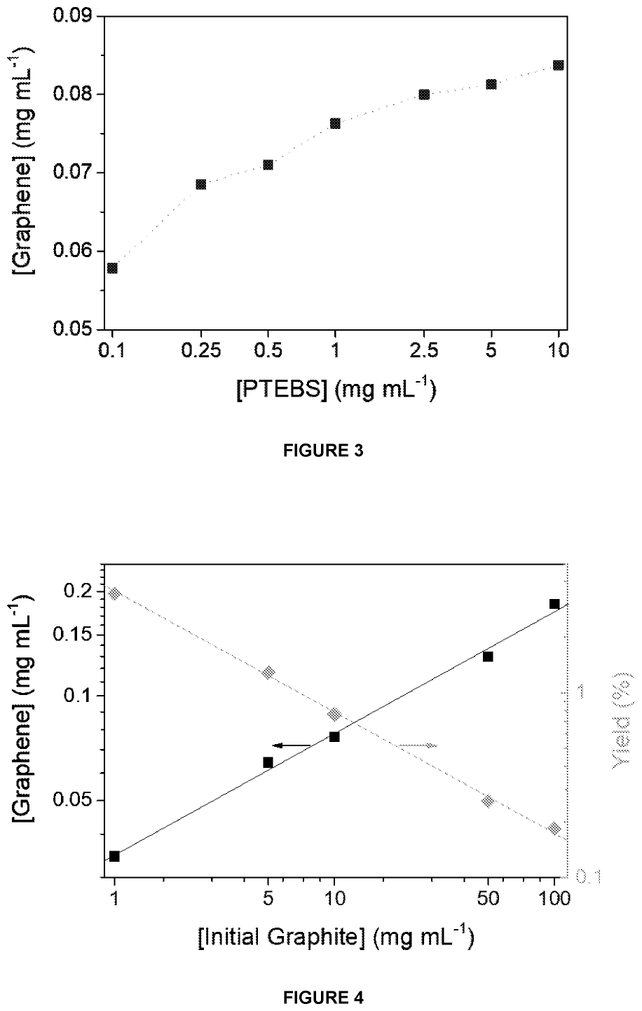

The effect of amphiphilic molecules on graphene exfoliation as a function of varying the initial PTEBS concentration from 0.1 to 10 mg mL⁻¹ was also studied, as shown in FIG. 3. It is noteworthy that while the initial PTEBS concentration was increased 100-fold, graphene concentrations were only slightly increased by ˜1.4 times (from −0.58 to ˜0.84 mg mL⁻¹). This suggests that the presence of an excess amount of free, unadsorbed PTEBS molecules does not play a significant role in graphene exfoliation, since only a limited amount of this polymeric amphiphilic molecule could be adsorbed onto the surface of graphene.

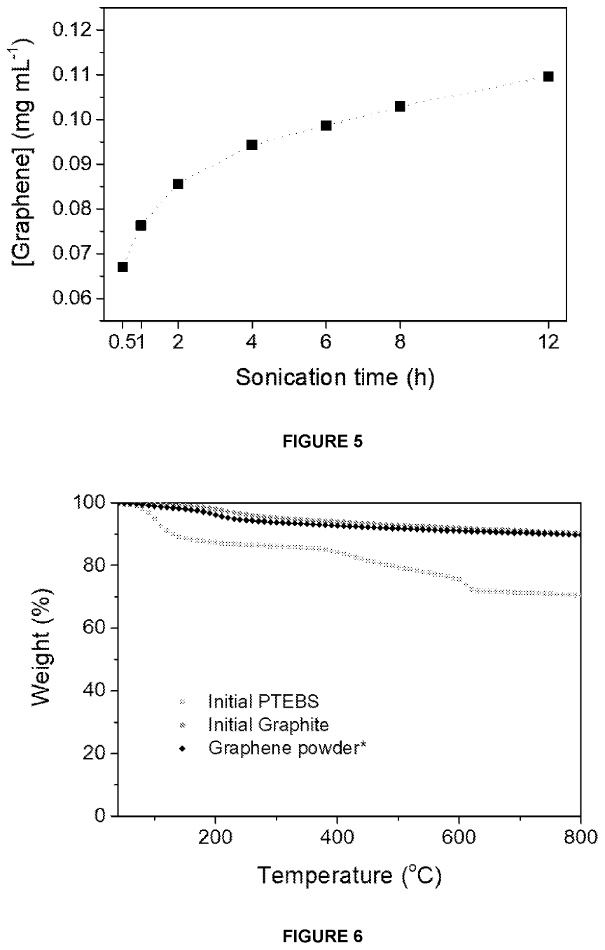

The effect of sonication time was also studied. The concentration of graphene in the dispersions increased gradually with sonication time up to 4 h, while longer ultrasound treatment did not result in appreciably higher concentrations of the exfoliated graphene (FIG. 5). Overall, the yield of the exfoliated graphene flakes was close to ˜1% relative to the weight of the starting graphite material in a typical experiment setting. The yield could be further increased up to ˜3.5% by decreasing the initial graphite concentration, which is a superior result, compared to prior studies [14,16,18,36].

It was also found that both the waste graphite starting material (after the mild centrifugation step) and the excess free PTEBS or PTAA molecules (after the purification step) were recyclable in this process.

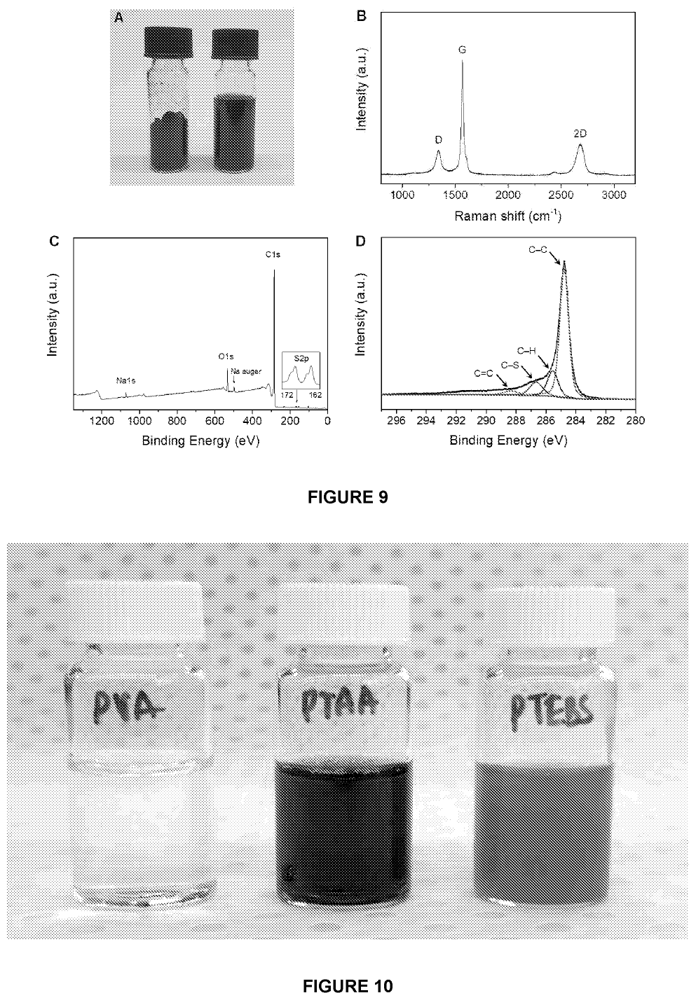

The stable homogeneous pristine graphene aqueous dispersions free from unadsorbed PTEBS molecules, could be readily processed into dry pristine graphene powders by lyophilization, and subsequently easily redispersed in water without the need for ultrasonication (FIG. 9A).

The quality of the PTEBS functionalised dry pristine graphene powder was characterized by Raman spectroscopy and X-ray photoelectron spectroscopy (XPS). FIG. 9B shows the Raman spectrum of graphene powder with 3 characteristic bands: D-band (˜1350 cm⁻¹), G-band (˜1580 cm⁻¹), and 2D-band (˜2700 cm⁻¹). In general, the D-band is related to the breathing mode of the sp2 carbon atoms, while the G-band corresponds to the in-plane vibrations of the graphene lattice, and the 2D-band is an overtone of the D-band [14,41]. As the defects of the graphene lattice such as sp3 defects, edges, or vacancies play an important role on activation of the D-band in the Raman spectrum, it is well established that the Raman D/G band intensity ratio (I_{D}/I_{G}) is associated with the degree of defects of the graphene lattice [42]. The dry pristine graphene powder exhibited a relatively weak D-band with (I_{D}/I_{G}) of ˜0.2, indicating a very low content of defects. This suggests that the graphene produced in the method of the invention had comparable quality to the surfactant and solvent exfoliated pristine graphene of the prior art [14,16,41].

XPS was used to give an insight into the chemical composition of the prepared PTEBS functionalized dry pristine graphene powder. Only carbon, oxygen, sodium, and sulfur were detected in the XPS survey spectrum (FIG. 9C). The presence of sulfur and sodium could only have originated from the thiophene and sodium sulfonated groups of the PTEBS molecules since neither the starting graphite material nor the liquid medium contain these atoms. A sodium auger peak was also observed at ˜497 eV, which occurred with the presence of sodium atoms underneath carbon, suggesting the strong adsorption of the PTEBS molecules to the surface of graphene [43].

The mass ratio of PTEBS to graphene was estimated to be extremely low at ˜0.02, which was confirmed by thermogravimetric analysis (FIG. 6) of the prepared dry pristine graphene powder.

FIG. 9C shows the core level C 1s spectrum of the prepared PTEBS functionalized dry pristine graphene powder. A dominant peak located at a binding energy of ˜284.8 eV, representing the (C—C) bonding of graphitic sp² carbon [16,44]. The additional small peaks located at 285.6, 286.7 and 288.5 eV were assigned to the spa carbon (C—H), sulfonated carbon (C—S) and (C═O) double bond [44-48], respectively. As the Raman spectrum confirmed that there were no significant defects on the graphene basal plane, these minor peaks in the XPS spectrum are likely to have originated from the adsorbed PTEBS molecules on graphene surface. Therefore, the characterisation data demonstrates that the dry pristine graphene powder produced in accordance with the method of the invention is high quality, non-oxidative and free of defects with comparable characteristics to the pristine graphenes produced by other solvent/surfactant/polymer assisted liquid-phase exfoliation processes of the prior art [14,16,36,41,49]. However, the present invention achieves this result without the problems of the prior art associated with toxic high boiling point solvents and/or excessive stabilizers and dispersants, and/or low yields.

### Example 3— Stable Homogeneous Dispersions of Pristine Graphene

The formulation of stable homogeneous dispersions from the prepared dry pristine graphene powders is simple and straightforward, as the prepared graphene powders are self-dispersible in aqueous solution. In fact, the as—produced graphene powders can be readily redispersed in water by mild-sonication or even simple vortex-mixing, yielding stable and concentrated graphene dispersions. Most notably, graphene concentrations in aqueous phase as high as 10 mg mL⁻¹ could be attained by mild-sonication without any difficulty.

The morphology of the PTEBS functionalized graphene flakes in the resultant graphene dispersions was studied by transmission electron microscopy (TEM), scanning electron microscope (SEM), and atomic force microscopy (AFM).

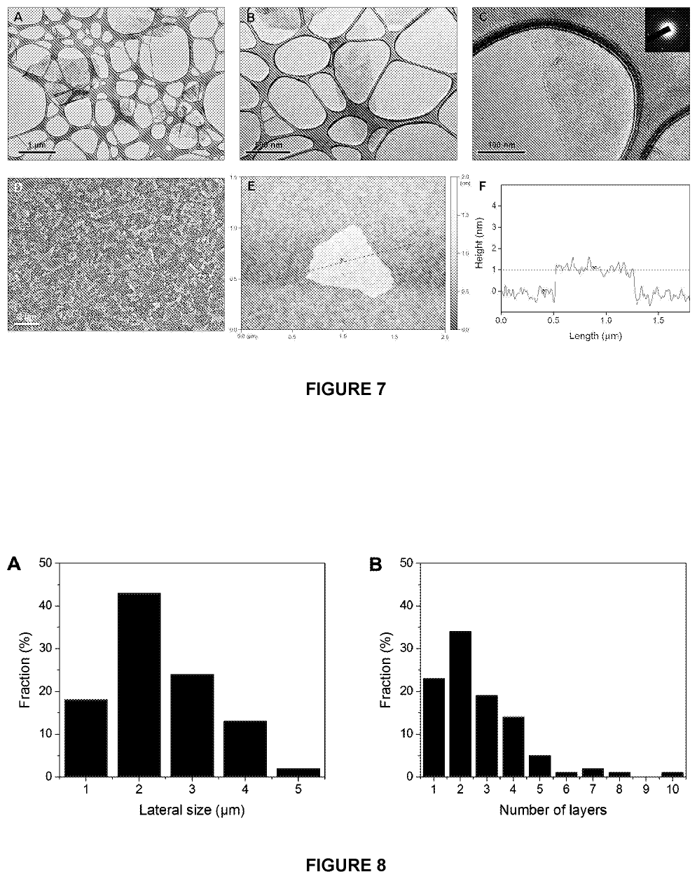

The TEM images shows that thin flakes of graphene were successfully produced, with different lateral sizes ranging from 500 to 2500 nm (FIGS. 7A-7C). Selected-area electron diffraction pattern at the central part of the graphene flake displays a typical six-fold symmetric diffraction pattern (inset in FIG. 7C), indicating the presence of monolayer graphene [50].

For statistical analysis of the flake size, graphene sheets were transferred on to an alumina membrane by vacuum filtration of a dilute graphene dispersion. FIG. 7D shows an SEM image of the individual graphene flakes that uniformly distributed throughout the membrane.

The lateral size (the largest dimension) of more than 250 graphene flakes was measured, showing that the predominant size distribution was between 1 and 3 μm (FIG. 8A).

Some larger flakes with size up to 5 μm were also observed. FIG. 7E shows an AFM image of a typical graphene flake on a Si wafer. The height profile acquired across the flake revealed its corresponding thickness of close to ˜1 nm (FIG. 7F), which is comparable to the thickness of monolayer surfactant-exfoliated graphene [14,36].

The statistical analysis of 100 graphene sheets revealed that most flakes had a thickness of less than 5 nm, indicating that ˜95% of the graphene sheets were composed of less than 5 layers (FIG. 8B), more than 30% were bilayer graphene and more than 20% were monolayer graphene.

### Example 4—Comparative Example

To test the hypothesis that the excellent performance of the polymeric amphiphilic molecules of the invention on stabilization of the graphene dispersions can be attributed to the synergic effect of π-π stacking interactions of the aromatic moiety of the polymeric amphiphilic molecules, non-covalently attaching itself to the basal plane of the graphene surface and the polar moiety at the opposite end of the polymeric amphiphilic molecules, conferring hydrophilicity on the exfoliated graphene, an additional experiment was carried out using Polyvinyl Alcohol (PVA), for comparison to the performance of PTEBS and PTAA.

PVA lacks an aromatic moiety or conjugated double bond system, and would therefore not be capable of non-covalently attaching itself to the basal plane of the graphene surface via π-π stacking interactions in accordance with the present invention. Accordingly, when subjected to the purification step of the method of the invention, wherein unadsorbed dispersants or stabilizers are removed from the graphene suspension, it was expected that the PVA might be completely removed, resulting in aggregation of the exfoliated graphene, and an inability to form a stable homogeneous suspension.

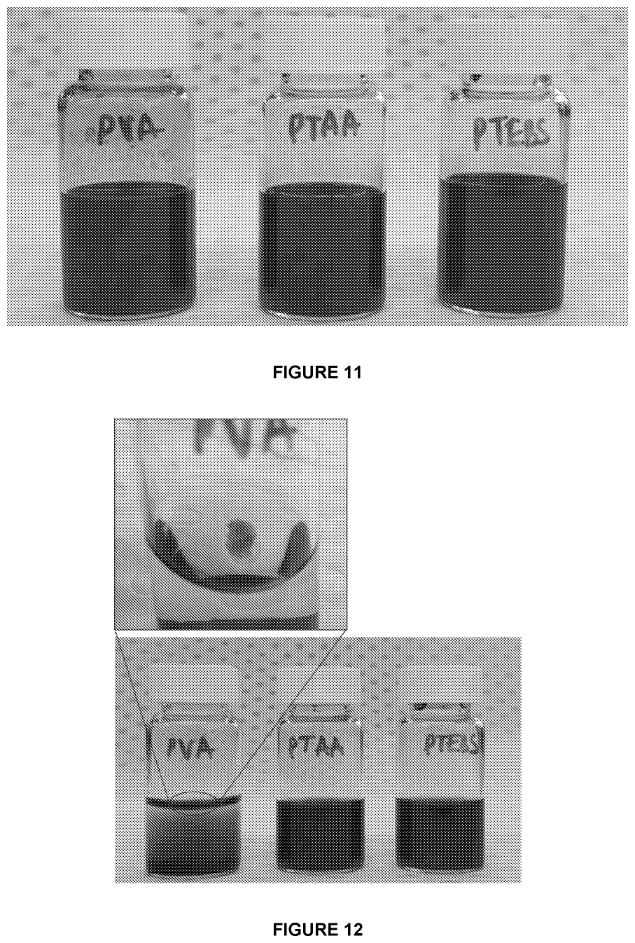

For this experiment, solutions containing 10 mg mL⁻¹ PVA, 1 mg mL⁻¹ PTEBS and 1 mg mL⁻¹ PTAA were prepared (FIG. 10; PVA left, PTAA middle, PTEBS right). Previous attempts using PVA at 1 mg mL⁻¹ had shown that at such low concentrations, PVA was unable to achieve stable graphene dispersion. Prior art methods for dispersing graphene typically employ PVA at a concentration of 30 mg mL⁻¹. For the PTAA solution, pH of the solution was adjusted to pH=12 in order to ionize the terminal acetic acid group, prior to the addition of the graphite powder. 100 mg of the graphite powder was added to 10 mL of each of the three solutions and they were ultrasonicated for 60 min. The resulting dispersions were centrifuged at 2000 rpm for 30 min to remove any remaining graphite starting material, and the supernatants were collected for further purification. The resulting supernatants were a stable black colour, indicating the successful exfoliation and stabilization of graphene for all three samples (FIG. 11; PVA left, PTAA middle, PTEBS right).

To remove any unadsorbed PVA, PTEBS or PTAA from the graphene dispersions, the suspensions were subjected to two cycles of purification by ultracentrifugation at 60000 rpm for 60 min to sediment down the graphene flakes, and redispersion in pure water (adjusted to pH=12 for PTAA) by sonication for 2 min yielding graphene dispersions without the presence of unadsorbed dispersant in the solutions (FIG. 12; PVA left, PTAA middle, PTEBS right).

After this step, PVA was unable to produce a stable graphene dispersion. The PVA mixture showed significant precipitation after just 10 min (FIG. 12, left). Furthermore, the presence of graphitic scum on the surface of the water was observed (FIG. 12, inset), indicating the aggregation of hydrophobic graphene on the surface of the water.

The results support the hypothesis that the excellent performance of the polymeric amphiphilic molecules of the invention on stabilization of the graphene dispersions can be attributed to the synergic effect of π-π stacking interactions of the aromatic moiety of the polymeric amphiphilic molecules, non-covalently attaching itself to the basal plane of the graphene surface and the polar moiety at the opposite end of the polymeric amphiphilic molecules, conferring hydrophilicity on the exfoliated graphene, and provide a principle of general application whereby stable redispersible dry pristine graphene powders can be manufactured in accordance with the method of the present invention. The standard tests provided by the method described in this comparative example enable the testing of any polymeric amphiphilic molecule comprising a moiety capable of non-covalently attaching itself to the basal plane of the graphene surface via π-π stacking interactions, in order to arrive at the stable redispersible pristine graphene powder compositions of the present invention, without undue burden or the need for further invention.

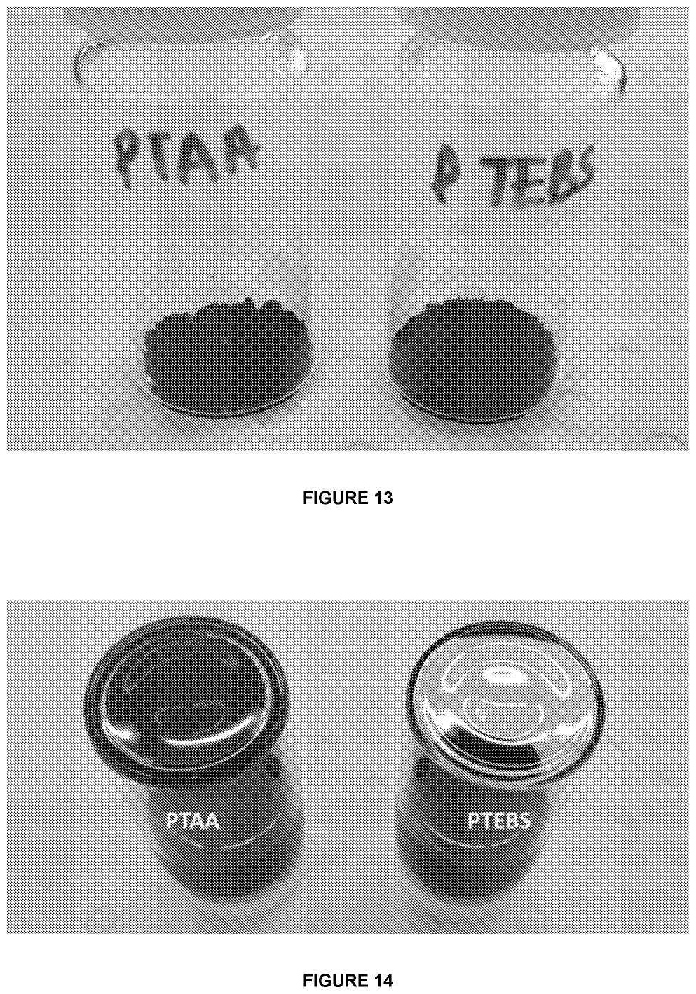

The PTAA and PTEBS samples, which were able to successfully produce a stable graphene dispersion were further processed by lyophilization for 3 days to produce dry and light weight graphene powders (FIG. 13; PTAA left, PTEBS right), yielding 2.1 mg (PTAA) and 3.6 mg (PTEBS) of dry pristine graphene powder. Without wishing to be bound by theory, it is thought that the PTEBS was able to produce a higher yield of exfoliated pristine graphene than PTAA, as a result of the more strongly solubilising sodium sulfonated moieties of PTEBS compared to the acetic acid functional groups of PTAA. Nevertheless, both polymeric amphiphilic molecules were successful in providing stable dispersions of pristine graphene.

The dry samples of PTAA and PTEBS were redispersed in water (pH=12 for PTAA) at 0.1 mg mL⁻¹. While PTEBS remained stable, the PTAA sample presented more difficulty with redispersion (FIG. 14; PTAA left, PTEBS right). However, in both instances, no signs of graphitic scum on the liquid surface were observed. Graphene can be dispersed in the solution with PTAA or PTEBS without any sign of hydrophobicity as was observed with the PVA sample, indicating that hydrophilicity has been successfully conferred upon the exfoliated graphene flakes as a result of the π-π stacking of the both polymeric amphiphilic molecules.

To address the difficulties observed with redispersion of the PTAA sample, redispersion was conducted under increased humidity of the samples. The graphene powders produced with PTEBS and PTAA were placed on a humidity oven for 6 h to increase the humidity of the samples to 70%. Afterward, the humidified samples of PTEBS and PTAA were redispersed in water (pH=12 for PTAA).

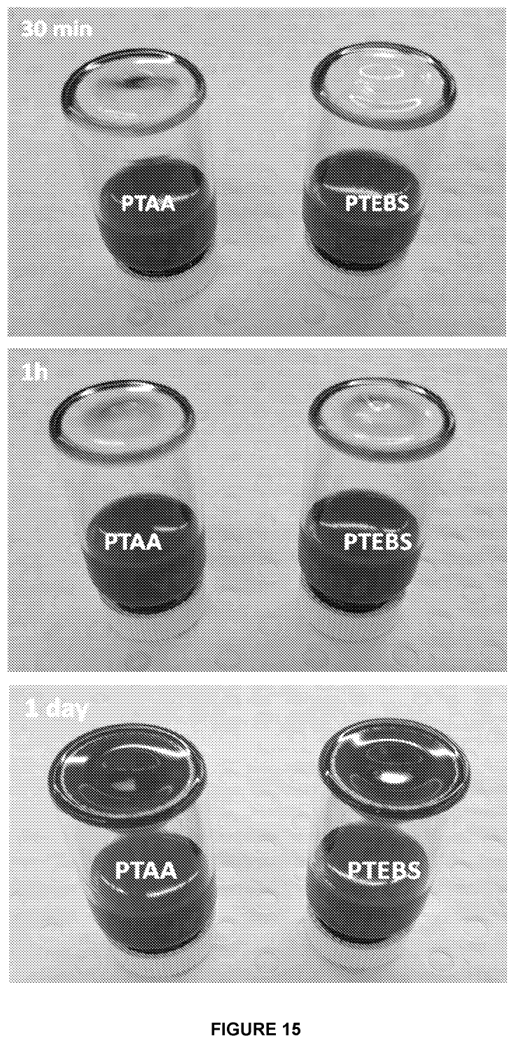

With increased humidity, both samples were stable for more than 1h without precipitation (FIG. 15, middle). After 1 day, a small amount of precipitation was observed, however, the amount was not significant (FIG. 15, bottom). In both cases, dry graphene powder was successfully redispersed in water.

The conductivity of thin films prepared from the three graphene samples was measured with the following results: PVA: ˜2620 PTAA: ˜327 PTEBS: ˜33 D/sq. These results demonstrate the superior conductivity observed with the pristine graphene produced in accordance with the present invention, being at least an order of magnitude better than prior art methods involving graphite exfoliation in the presence of PVA (two orders of magnitude in the case of PTEBS).

### Example 5—Graphene Inks for 3D and 2D Printing and Production of Microlattice Electrocatalyst Supports and Flexible Conductive Circuits

Printing technology is one of the foremost inventions for advanced layer manufacturing, which enable feasible and cost-effective strategies for large-scale fabrication of modern electronics. To give more insight into the potential of the formulated graphene dispersions for additive layer processing, a study was conducted into the printability of the dispersions with respect to the printing indicator.

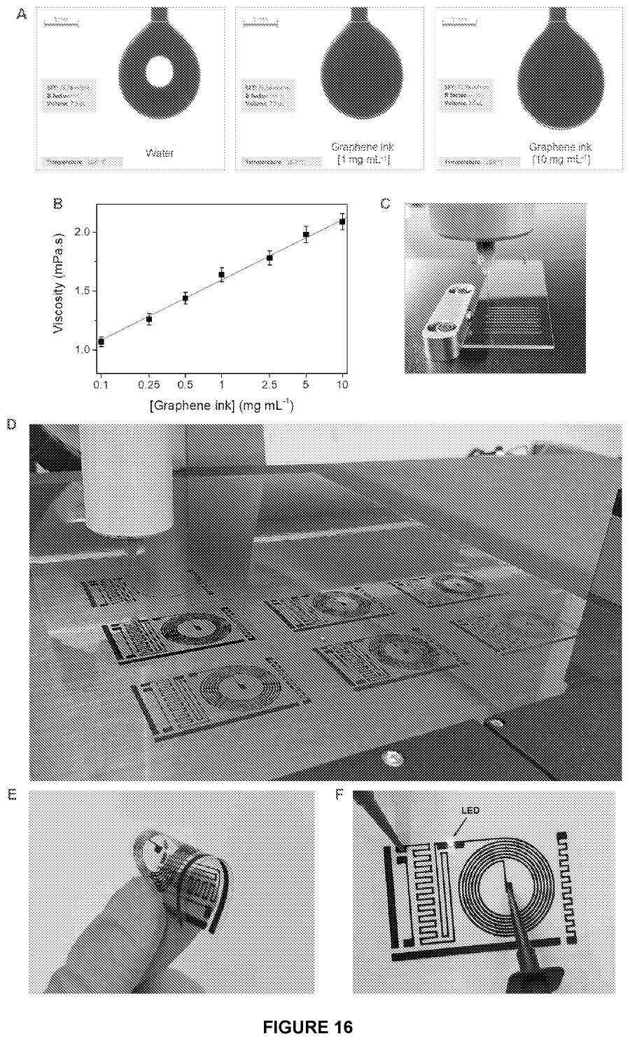

As the formulated graphene dispersions need to be ejected through the printing nozzle to be printable, fluid mechanics (including viscosities and surface tensions) are of significance to the printability of the inks. Interestingly, the present inventors have found that the surface tension of graphene inks produced using the methods described herein at various concentrations were mainly unchanged, and were comparable to that of pure water (˜72 mN m⁻¹), as shown in FIG. 16A. This could be due to the fact that the graphene inks were formulated without free surfactants or other unadsorbed dispersants or stabilizers.

While the pristine graphene flakes of the invention were self-dispersed in water and their composition accounts for less than 1% of the mass of the inks, the densities and intermolecular attractions of the inks remained relatively constant, therefore, not affecting the surface tension of the inks.

As a measure of the resistance of a fluid to being deformed under shear forces, the viscosity of the inks provides a good insight into flow variations under many typical printing conditions. FIG. 16B shows that the viscosity of the inks steadily increased in a directly proportional and linear relationship with graphene concentration. Graphene ink dispersions were formulated at concentrations of 0.1, 0.25, 0.5, 1, 2.5, 5 and 10 mg mL⁻¹, and the highest viscosity achieved was ˜2.1 mPas at a graphene concentration of 10 mg mL⁻¹.

The formulated graphene ink was housed in a 10 mL syringe barrel with a 30GA precision dispensing needle (Nordson™ Australia) and mounted onto a three-axis dispensing system (GeSim BioScaffolder™ 3.1). Printing was performed at room temperature with 80 kPa extrusion air pressure, and a stage speed of 10 mm s⁻¹.

For 2D printing of two-dimensional graphene patterns, a layer of graphene ink was printed onto a glass slide or a PET substrate by a single printing pass (FIGS. 16C & 16D). The printed patterns were allowed to dry under ambient conditions for 1 h prior to transfer to a vacuum chamber for extensive drying.

The dispersions printed onto PET substrates (FIG. 16D), resulted in flexible conductive circuits with excellent flexibility to withstand bending without failure (FIG. 16E). The printed patterns exhibited superior electrical conductivity of ˜30 Ω/sq without being subjected to thermal annealing. The ability of the flexible conductive circuits of the present invention to withstand such severe bending without failure was confirmed via operation of a light emitting diode (LED) incorporated into the circuit, as shown in FIG. 16F.

For 3D printing of three-dimensional graphene structures, the formulated graphene ink was printed into a bath containing 5 wt % carboxymethylcellulose sodium salt (CMC) solution as coagulant. Three-dimensional periodic microlattices were assembled by patterning an array of parallel (rod-like) filaments in a meander line pattern in the horizontal plane such that the orientation of each successive layer was orthogonal to the previous layer. After printing, the 3D printed graphene structure was immersed into liquid nitrogen to implement the critical freezing process for 30 min and then transferred into a freeze dryer for lyophilisation at −80° C. for 48 h. The pristine graphene microlattice thus produced is highly suitable for use as an electrocatalyst support or porous electrode by virtue of the high conductivity of the microlattice structure [57-59].

Articles printed using the PTEBS functionalised graphene inks of the present invention exhibited superior electrical conductivities of ˜30 Ω/sq without the need for carrying out thermal annealing.

The formulated pristine graphene dispersions/inks of the present invention are suitable for a diverse range of printing and coating applications.

### Example 6—Wet-Spinning of Pristine Graphene Fibers

Graphene fiber has recently emerged as an important application of graphene because it integrates the remarkable properties of individual graphene sheets into the useful, macroscopic characteristics of fibers. Owing to its mechanical flexibility graphene fibers show great promise for the manufacture of textiles, while also maintaining the unique advantages of excellent electrical conductivity. Graphene fibers show great potential in various fields (e.g. brain-machine interfaces for the restoration of sensory and motor function and the treatment of neurological disorders).

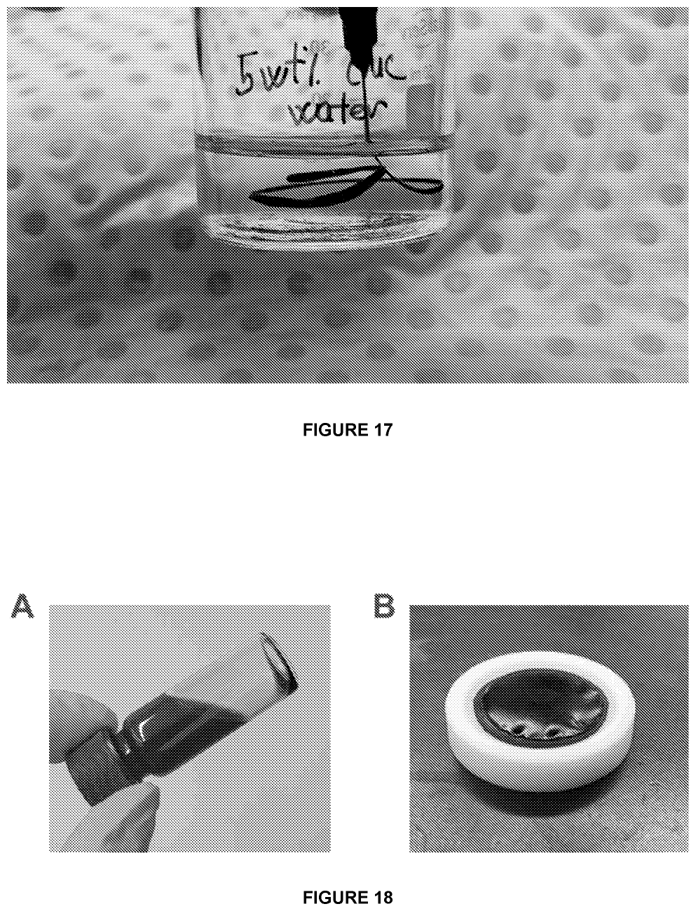

However, traditional methods only allow for the fabrication of graphene fibers from graphene oxide, with correspondingly compromised electrical properties. Herein, the inventors have demonstrated the fabrication of pristine graphene fibers directly from the redispersible pristine graphene powders of the invention without involving any oxidation processes (FIG. 17).

Wet-spinning trials were carried out using a custom-built wet-spinning apparatus. A concentrated graphene dispersion (5 mg mL⁻¹) of PTEBS functionalised pristine graphene powder in accordance with the present invention, dispersed in aqueous poly(1-vinyl-3-ethylimidazolium bromide) solution (1 wt %), was injected into a coagulation bath containing 5 wt % carboxymethylcellulose sodium salt (CMC) using a syringe pump (10 mL min⁻¹). After removal from the coagulation bath, the graphene fibers were immersed into liquid nitrogen to implement the critical freezing process for 30 min and then transferred into a freeze dryer for lyophilisation at −80° C. for 48 h.

To the best of the inventors' knowledge, this is the first successful demonstration of wet-spinning of pristine graphene fibers, which hold great promise for their potential applications in biomedical, electronics, electrochemical and brain-machine interfaces.

### Example 7—Fabrication of Pristine Graphene-Based Nanocomposites

The redispersible pristine graphene powder of the present invention can also be used as a replacement for graphene oxide (GO), as a nanofiller for fabrication of graphene-based nanocomposites.

Prior art approaches to producing graphene dispersions for the fabrication of graphene-based nanocomposites generally employ GO as it possesses the advantage of being able to produce high concentration homogeneous aqueous dispersions (high dispersibility). However, the disadvantages associated with the use of GO are that it requires a post-fabrication reduction process in order to transform the GO sheets into reduced graphene oxide (rGO) and thereby restore its conductivity. The oxidation and reduction process generally damages the integrity of the graphene sheets to some extent, resulting in poorer conductivity performance compared to pristine graphene.

Further problems arise with the use of GO in the preparation of nanocomposites for biomedical applications as the process of chemical reduction to rGO typically involves harsh or toxic chemicals (hydrazine is the most commonly employed reducing agent for GO), requiring exhaustive purification processes to remove the residual chemicals. Thermal reduction is not a viable option either, where many biocompatible matrix materials are employed, as the high temperatures involved results in damage, decomposition or denaturation of such materials.

The redispersible pristine graphene powder of the present invention addresses these problems of the prior art by providing a form of pristine graphene that is capable of being homogeneously dispersed in aqueous solutions at concentrations comparable to GO, thereby enabling pristine graphene to be used as a nanofiller for fabrication of conductive graphene nanocomposites without the need of oxidation and reduction processes detrimental to the conductivity of the final product.

To demonstrate this capability of the present invention, 20 mg of the PTEBS functionalised pristine graphene powder was dispersed in 10 mL of water and mixed with 10 mL aqueous of silk fibroin solution (30 wt %) as matrix material, to produce a homogeneous graphene/silk fibroin dispersion (FIG. 18A). The mixture was transferred into a Teflon mold and sonicated for 1h using a Unisonics sonication bath. The sonication process induced physical-crosslinking, resulting in the self-assembly of graphene/silk fibroin into conductive hydrogels (FIG. 18B). The skilled addressee will recognize that other matrix materials including alternative peptides, polymers, biopolymers and oligomers may be employed in the fabrication of nanocomposite materials, as described in the prior art using GO [53-56].

The pristine graphene powder of the present invention is thus capable of producing conductive graphene/silk fibroin hydrogels without the need of a thermal or chemical reduction process as has been done previously using graphene oxide [51], and therefore is advantageously suitable for the fabrication of a wide range of graphene-based nanocomposites, particularly in such areas where thermal/chemical reduction processes are undesired, and/or where improved conductivity performance is required in the final product.

Characterization

UV-visible spectroscopy was performed on a Shimadzu™ UV-2600. The dispersions were diluted prior to measurement to obtain meaningful absorbance readings.

Raman spectrum of graphene powder was recorded using a HORIBA™ LabRAM HR Evolution with a 532 nm laser excitation.

XPS measurement was performed using a Thermo Scientific™ K-Alpha with a monochromated Al Kₐ X-ray source.

Thermogravimetric analyses (TGA) were performed on a PerkinElmer™ Pyris 1 TGA at a heating rate of 20° C./min under nitrogen.

Transmission electron microscopy (TEM) was carried out on a JEOL™ 1010 TEM. The samples for TEM were prepared by depositing a drop of the graphene dispersions on holey carbon grids and then allowing to dry at 60° C. for 24 h in a vacuum oven.

Scanning electron microscope (SEM) measurements were carried out on a FEI Nova NanoSEM™. The samples were prepared by vacuum filtration of diluted graphene dispersions onto alumina membranes and the films were dried at 60° C. overnight.

Atomic force microscopy (AFM) measurements were carried out on a MFP-3D Infinity AFM (Asylum Research™). The AFM sample was prepared by drop-casting the dispersion onto an 02 plasma-treated Si wafer.

Viscosity measurements were performed on a HR-2 Discovery hybrid rheometer (TA Instruments™).

Surface tensions of the dispersions were measured using a Kruss™ DSA25 tensiometer.

The sheet resistance of the printed graphene patterns were measured via the classic four-probe-method (also known as the four-point-probe method, or Van der Pauw method), using a Keithley™ 2450 source meter.

Modifications of the above-described modes of carrying out the various embodiments of this invention will be apparent to those skilled in the art based on the above teachings related to the disclosed invention. The above embodiments and examples of the invention are included solely for the purposes of exemplifying the present invention and should not be construed to be in any way limiting. They should not be understood as a restriction on the broad summary, disclosure or description of the invention as set out above.

Those skilled in the art will appreciate that the invention described herein is susceptible to variations and modifications other than those specifically described. The invention includes all such variation and modifications. The invention also includes all of the steps, features, formulations and compounds referred to or indicated in the specification, individually or collectively and any and all combinations or any two or more of the steps or features.

### REFERENCES

1. Novoselov, K. S.; Fal, V.; Colombo, L.; Gellert, P.; Schwab, M.; Kim, K. A roadmap for graphene. Nature 2012, 490, 192.
2. Garg, R.; Dutta, N.; Choudhury, N. Work function engineering of graphene. Nanomaterials 2014, 4, 267-300.
3. El-Kady, M. F.; Shao, Y.; Kaner, R. B. Graphene for batteries, supercapacitors and beyond. Nature Reviews Materials 2016, 1, 16033.
4. Raccichini, R.; Varzi, A.; Passerini, S.; Scrosati, B. The role of graphene for electrochemical energy storage. Nature materials 2015, 14, 271.
5. Tran, T. S.; Tripathi, K. M.; Kim, B. N.; You, I.-K.; Park, B. J.; Han, Y. H.; Kim, T. Three-dimensionally assembled Graphene/a-MnO2 nanowire hybrid hydrogels for high performance supercapacitors. Materials Research Bulletin 2017, 96, 395-404.
6. Zhang, Y.; Nayak, T. R.; Hong, H.; Cai, W. Graphene: a versatile nanoplatform for biomedical applications. Nanoscale 2012, 4, 3833-3842.
7. Bitounis, D.; Ali-Boucetta, H.; Hong, B. H.; Min, D. H.; Kostarelos, K. Prospects and challenges of graphene in biomedical applications. Advanced Materials 2013, 25, 2258-2268.
8. Perreault, F.; De Faria, A. F.; Elimelech, M. Environmental applications of graphene-based nanomaterials. Chemical Society Reviews 2015, 44, 5861-5896.
9. Myung, Y.; Jung, S.; Tung, T. T.; Tripathi, K. M.; Kim, T. Graphene-Based Aerogels Derived from Biomass for Energy Storage and Environmental Remediation. ACS Sustainable Chemistry & Engineering 2019, 7, 3772-3782.
10. Tran, T. S.; Dutta, N. K.; Choudhury, N. R. Graphene inks for printed flexible electronics: Graphene dispersions, ink formulations, printing techniques and applications. Advances in colloid and interface science 2018.
11. Neto, A. C.; Guinea, F.; Peres, N. M.; Novoselov, K. S.; Geim, A. K. The electronic properties of graphene. Reviews of modern physics 2009, 81, 109.
12. Jang, H.; Park, Y. J.; Chen, X.; Das, T.; Kim, M. S.; Ahn, J. H. Graphene-based flexible and stretchable electronics. Advanced Materials 2016, 28, 4184-4202.
13. Yu, X.; Cheng, H.; Zhang, M.; Zhao, Y.; Qu, L.; Shi, G. Graphene-based smart materials. Nature Reviews Materials 2017, 2, 17046.
14. Paton, K. R.; Varrla, E.; Backes, C.; Smith, R. J.; Khan, U.; O'Neill, A.; Boland, C.; Lotya, M.; Istrate, 0.M.; King, P. Scalable production of large quantities of defect-free few-layer graphene by shear exfoliation in liquids. Nature materials 2014, 13, 624.
15. Ciesielski, A.; Samori, P. Graphene via sonication assisted liquid-phase exfoliation. Chemical Society Reviews 2014, 43, 381-398.
16. Tran, T. S.; Park, S. J.; Yoo, S. S.; Lee, T.-R.; Kim, T. High shear-induced exfoliation of graphite into high quality graphene by Taylor—Couette flow. RSC Advances 2016, 6, 12003-12008.
17. Fowkes, F. M. Donor-acceptor interactions at interfaces. The Journal of Adhesion 1972, 4, 155-159.
18. Hernandez, Y.; Nicolosi, V.; Lotya, M.; Blighe, F. M.; Sun, Z.; De, S.; McGovern, I.; Holland, B.; Byrne, M.; Gun′Ko, Y. K. High-yield production of graphene by liquid-phase exfoliation of graphite. Nature nanotechnology 2008, 3, 563.
19. (ECHA), E. C. A. Candidate List of substances of very high concern for Authorisation (https://echa.europa.eu/web/guest/candidate-list-table). 2018.
20. Guardia, L.; Fernández-Merino, M.; Paredes, J.; Solis-Fernandez, P.; Villar-Rodil, S.; Martinez-Alonso, A.; TascÓn, J. High-throughput production of pristine graphene in an aqueous dispersion assisted by non-ionic surfactants. Carbon 2011, 49, 1653-1662.
21. Mohamed, A.; Ardyani, T.; Bakar, S. A.; Brown, P.; Hollamby, M.; Sagisaka, M.; Eastoe, J. Graphene-philic surfactants for nanocomposites in latex technology. Advances in colloid and interface science 2016, 230, 54-69.
22. Tran, T. S.; Dutta, N. K.; Choudhury, N. R. Graphene-Based Inks for Printing of Planar Micro-Supercapacitors: A Review. Materials 2019, 12, 978.
23. Yang, S.; Bruner, S.; Wu, Z.-S.; Liu, Z.; Parvez, K.; Dong, R.; Richard, F.; Samori, P.; Feng, X.; Mullen, K. Organic radical-assisted electrochemical exfoliation for the scalable production of high-quality graphene. Journal of the American Chemical Society 2015, 137, 13927-13932.
24. Najafabadi, A. T.; Gyenge, E. High-yield graphene production by electrochemical exfoliation of graphite: novel ionic liquid (IL)—acetonitrile electrolyte with low IL content. Carbon 2014, 71, 58-69.
25. Su, C.-Y.; Lu, A.-Y.; Xu, Y.; Chen, F.-R.; Khlobystov, A. N.; Li, L.-J. High-quality thin graphene films from fast electrochemical exfoliation. ACS nano 2011, 5, 2332-2339.
26. Yang, Y.; Lu, F.; Zhou, Z.; Song, W.; Chen, Q.; Ji, X. Electrochemically cathodic exfoliation of graphene sheets in room temperature ionic liquids N-butyl, methylpyrrolidinium bis (trifluoromethylsulfonyl) imide and their electrochemical properties. Electrochimica Acta 2013, 113, 9-16.
27. Abdelkader, A.; Cooper, A.; Dryfe, R.; Kinloch, I. How to get between the sheets: a review of recent works on the electrochemical exfoliation of graphene materials from bulk graphite. Nanoscale 2015, 7, 6944-6956.
28. Yang, S.; Lohe, M. R.; Müllen, K.; Feng, X. New-Generation Graphene from Electrochemical Approaches: Production and Applications. Advanced Materials 2016, 28, 6213-6221.
29. Parvez, K.; Wu, Z.-S.; Li, R.; Liu, X.; Graf, R.; Feng, X.; Mullen, K. Exfoliation of graphite into graphene in aqueous solutions of inorganic salts. Journal of the American Chemical Society 2014, 136, 6083-6091.
30. Paredes, J. I.; Munuera, J. Recent advances and energy-related applications of high quality/chemically doped graphenes obtained by electrochemical exfoliation methods. Journal of Materials Chemistry A 2017, 5, 7228-7242.
31. Munuera, J.; Paredes, J.; Villar-Rodil, S.; Ayan-Varela, M.; Martinez-Alonso, A.; Tascon, J. Electrolytic exfoliation of graphite in water with multifunctional electrolytes: en route towards high quality, oxide-free graphene flakes. Nanoscale 2016, 8, 2982-2998.
32. Rodriguez-Ropero, F.; Casanovas, J.; Aleman, C. Ab initio calculations on Tr-stacked thiophene dimer, trimer, and tetramer: Structure, interaction energy, cooperative effects, and intermolecular electronic parameters. Journal of computational chemistry 2008, 29, 69-78.
33. Santra, S.; Hu, G.; Howe, R.; De Luca, A.; Ali, S.; Udrea, F.; Gardner, J.; Ray, S.; Guha, P.; Hasan, T. CMOS integration of inkjet-printed graphene for humidity sensing. Scientific reports 2015, 5, 17374.
34. Li, D.; Müller, M. B.; Gilje, S.; Kaner, R. B.; Wallace, G. G. Processable aqueous dispersions of graphene nanosheets. Nature nanotechnology 2008, 3, 101.
35. Sun, Z.; Masa, J.; Liu, Z.; Schuhmann, W.; Muhler, M. Highly concentrated aqueous dispersions of graphene exfoliated by sodium taurodeoxycholate: dispersion behavior and potential application as a catalyst support for the oxygen-reduction reaction. Chemistry—A European Journal 2012, 18, 6972-6978.
36. Lotya, M.; Hernandez, Y.; King, P. J.; Smith, R. J.; Nicolosi, V.; Karlsson, L. S.; Blighe, F. M.; De, S.; Wang, Z.; McGovern, I. Liquid phase production of graphene by exfoliation of graphite in surfactant/water solutions. Journal of the American Chemical Society 2009, 131, 3611-3620.
37. Lotya, M.; King, P. J.; Khan, U.; De, S.; Coleman, J. N. High-concentration, surfactant-stabilized graphene dispersions. ACS nano 2010, 4, 3155-3162.
38. Vadukumpully, S.; Paul, J.; Valiyaveettil, S. Cationic surfactant mediated exfoliation of graphite into graphene flakes. Carbon 2009, 47, 3288-3294.
39. Coleman, J. N. Liquid exfoliation of defect-free graphene. Accounts of chemical research 2012, 46, 14-22.
40. Sham, A. Y.; Notley, S. M. A review of fundamental properties and applications of polymer—graphene hybrid materials. Soft Matter 2013, 9, 6645-6653.
41. Khan, U.; O'Neill, A.; Lotya, M.; De, S.; Coleman, J. N. High-concentration solvent exfoliation of graphene. Small2010, 6, 864-871.
42. Eckmann, A.; Felten, A.; Mishchenko, A.; Britnell, L.; Krupke, R.; Novoselov, K. S.; Casiraghi, C. Probing the nature of defects in graphene by Raman spectroscopy. Nano letters 2012, 12, 3925-3930.
43. Luo, Z.; Wang, J.; Qu, L.; Jia, J.; Jiang, S.; Zhou, X.; Wu, X.; Wu, Z. Visible-light-driven photocatalytic reduction of Cr (VI) on magnetite/carboxylate-rich carbon sheets. New Journal of Chemistry 2017, 41, 12596-12603.
44. Merel, P.; Tabbal, M.; Chaker, M.; Moisa, S.; Margot, J. Direct evaluation of the sp3 content in diamond-like-carbon films by XPS. Applied Surface Science 1998, 136, 105-110.
45. Leung, T.; Man, W.; Lim, P.; Chan, W.; Gaspari, F.; Zukotynski, S. Determination of the sp3/sp2 ratio of aC:H by XPS and XAES. Journal of non-crystalline solids 1999, 254, 156-160.
46. Stankovich, S.; Dikin, D. A.; Piner, R. D.; Kohlhaas, K. A.; Kleinhammes, A.; Jia, Y.; Wu, Y.; Nguyen, S. T.; Ruoff, R. S. Synthesis of graphene-based nanosheets via chemical reduction of exfoliated graphite oxide. carbon 2007, 45, 1558-1565.
47. Kovtyukhova, N. I.; Wang, Y.; Berkdemir, A.; Cruz-Silva, R.; Terrones, M.; Crespi, V. H.; Mallouk, T. E. Non-oxidative intercalation and exfoliation of graphite by Brensted acids. Nature chemistry 2014, 6, 957.
48. Hong, S.; Boerio, F. Effect of silanes on the interfacial compositions of epoxy/metal adhesive bonds: XPS and RAIR analyses. Surface and interface analysis 1994, 21, 650-658.
49. Hou, B.; Liu, H.; Qi, S.; Zhu, Y.; Zhou, B.; Jiang, X.; Zhu, L. Preparation of pristine graphene in ethanol assisted by organic salts for nonenzymatic detection of hydrogen peroxide. Journal of colloid and interface science 2018, 510, 103-110.
50. Meyer, J. C.; Geim, A. K.; Katsnelson, M. I.; Novoselov, K. S.; Booth, T. J.; Roth, S. The structure of suspended graphene sheets. Nature 2007, 446, 60.
51. Balu, R.; Reeder, S.; Knott, R.; Mata, J.; de Campo, L.; Dutta, N. K.; Choudhury, N. R. Tough photocrosslinked silk fibroin/graphene oxide nanocomposite hydrogels. Langmuir 2018, 34, 9238-9251
52. Aydin, M., Durmus, Z., Kavas, H., Esat, B., SÖzeri, H., Baykal, A., & Toprak, M. S.; “Synthesis and characterization of poly (3-thiophene acetic acid)/Fe3O4 nanocomposite.” Polyhedron, 2011, 30(6), pages 1120-1126.
53. R. Balu, S. Reeder, R. Knott, J. Mata, L. de Campo, N. K. Dutta, N. Roy Choudhury, Tough photocrosslinked silk fibroin/graphene oxide nanocomposite hydrogels, Langmuir 34 (31), 9238-9251
54. R. Balu, P. Dorishetty, J. P. Mata, A. J. Hill, N K. Dutta, N. Roy Choudhury, Tuning the hierarchical structure and resilience of resilin-like polypeptide hydrogels using graphene oxide ACS Applied Bio Materials, 2020, https://doi.org/10.102/acsabm.0c01088
55. 0. M. Istrate, Keith R. Paton, U. Khan, Arlene O'Neill, Alan P. Belled, Jonathan N. Coleman, Reinforcement in melt-processed polymer—graphene composites at extremely low graphene loading level, Carbon, 2014, 78, 243-249.
56. Wei-Hao Liao, Shin-Yi Yang, Sheng-Tsung Hsiao, Yu-Sheng Wang, Shin-Ming Li, Chen-Chi M. Ma, Hsi-Wen Tien, and Shi-Jun Zeng, Effect of Octa(aminophenyl) Polyhedral Oligomeric Silsesquioxane Functionalized Graphene Oxide on the Mechanical and Dielectric Properties of Polyimide Composites ACS Appl. Mater. Interfaces 2014, 6, 15802-15812.
57. H. Huang, M. Yan, C. Yang, H. He, Q. Jiang, L. Yang, Z. Lu, Z. Sun, X. Xu,Y. Bando, and Y. Yamauchi, Graphene Nanoarchitectonics: Recent Advances in Graphene-Based Electrocatalysts for Hydrogen Evolution Reaction, Adv. Mater. 2019, 31, 1903415.
58. K. K. Karuppanan, A. V. Raghu, M. Kumar Panthalingal, V. Thiruvenkatam, K. P. and B. Pullithadathil, 3D-porous electrocatalytic foam based on Pt@Ndoped graphene for high performance and durable polymer electrolyte membrane fuel cells, Sustainable Energy Fuels, 2019, 3, 996-1011.
59. J. Lai, A. Nsabimana,R. Luque, and G. Xu1,3D Porous Carbonaceous Electrodes for Electrocatalytic Applications, Joule, 2018, 2, 76-93.

1. A dry graphene powder composition comprising;
pristine graphene flakes, wherein the pristine graphene flakes are non-covalently functionalised with polymeric amphiphilic molecules; and wherein the dry graphene powder composition is capable of dispersion in aqueous or alcoholic media, or in water, or in an alcohol/water mixture, to form a stable homogeneous dispersion of pristine graphene in the absence of free dispersants or stabilizers;
wherein the polymeric amphiphilic molecules comprise;
a) a terminal aromatic moiety or conjugated double-bond moiety for non-covalently functionalising the pristine graphene flakes via π-π stacking adsorption thereto;
b) a terminal and optionally ionisable polar moiety for imparting hydrophilicity to the pristine graphene flakes; and
c) wherein the polymeric amphiphilic molecules are molecules in accordance with Formula I; 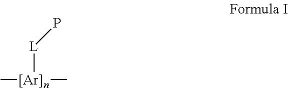
wherein;
Ar is an aromatic moiety;
P is an optionally ionisable polar moiety or a salt thereof; n is an integer of between 20 and 350; L is a linker independently selected from the group consisting of; a bond, C₁₋₂₀alkanediyl, C₁₋₂₀ heteroalkanediyl, C₁₋₂₀alkenediyl, C₁₋₂₀heteroalkenediyl, C₁₋₂₀alkynediyl, and C₁₋₂₀heteroalkynediyl.

2. The dry graphene powder composition of claim 1, wherein;
(i) Ar is a substituted or unsubstituted aromatic moiety independently selected from the group consisting of; thienyl, phenyl, biphenyl, naphthyl, indanyl, indenyl, fluorenyl, pyrenyl, pyridyl, pyrazinyl, pyrimidinyl, pyrrolyl, pyrazolyl, imidazolyl, thiazolyl, oxazolyl, isooxazolyl, thiadiazolyl, triazolyl, oxadiazolyl, thiophenyl, furanyl, quinolinyl, indolyl, and isoquinolinyl moieties; and/or
(ii) P is a polar moiety independently selected from the group consisting of; sulfonate, carboxylate, nitrate, sulfate, carboxamide, amine, substituted amine, quaternary amine, hydroxy, alkyloxy, sulphide, thiol, nitro, and nitrile moieties, or salts thereof where P is an ionisable group.

3. The dry graphene powder composition of claim 1 or claim 2, wherein;
Ar is thienyl; and/or
P is sulfonate, carboxylate or salts thereof; and/or L is —C₁₋₈alkyl—O—C₁₋₈alkyl—, —C₁₋₈alkyl—, —2-ethyloxy-4-butyl—, or methylene.

4. The dry graphene powder composition of any one of claims 1 to 3, wherein the compound of Formula I is poly-[2-(3-thienyl)ethyloxy-4-butylsulfonate] sodium salt (PTEBS), or poly-(3-thiophene acetic acid) (PTAA).

5. The dry graphene powder composition of any one of claims 1 to 4, wherein;
a) the polymeric amphiphilic molecules comprise less than 50% by weight of the composition; and/or
b) the polymeric amphiphilic molecules comprise approximately 2% by weight of the composition; and/or
c) the conductivity measured as sheet resistance of a dried thin film prepared therefrom is better than 350 Ω/sq; and/or
d) the conductivity measured as sheet resistance a dried thin film prepared therefrom is better than 35 Ω/sq; and/or
e) the conductivity measured as sheet resistance a dried thin film prepared therefrom is approximately 30 Ω/sq; and/or
f) the composition comprises pristine graphene flakes with a height profile as determined by Atomic Force Microscopy of approximately 1 nm; and/or
g) the lateral size of at least 50% of the pristine graphene flakes as determined by Scanning Electron Microscopy is a maximum of 2 μm; and/or
h) the number of layers of graphene within at least 50% of the pristine graphene flakes as determined by Atomic Force Microscopy is a maximum of 2.

6. A method of preparing the dry graphene powder composition as defined in any one of claims 1 to 5 comprising;
a) providing a graphite starting material, wherein the graphite starting material is natural graphite, or any type of non-oxidised graphite including but not limited to synthetic graphite, expandable graphite, intercalated graphite, electrochemically exfoliated graphite or recycled graphite;
b) optionally, pre-treating the graphite starting material by alternately soaking the graphite in liquid nitrogen and absolute ethanol to trigger modest expansion of the graphite layers, and/or by electrochemically exfoliating graphite to produce graphite particles, optionally wherein the electrochemical exfoliation is;
(i) anodic electrochemical exfoliation; and/or
(ii) conducted in an aqueous electrolyte; and/or
(iii) conducted in aqueous ammonium sulfate; and/or
(iv) conducted in the presence of an antioxidant; and/or
(v) conducted in the presence of (2,2,6,6-Tetramethylpiperidin-1-yl)oxyl (TEMPO);
optionally further wherein the graphite particles produced in the pre-treatment step are filtered, washed and dried before step c), optionally wherein filtering, washing and drying the graphite particles comprises filtering and washing alternately with water and ethanol, followed by drying under reduced pressure;
c) exfoliating and simultaneously non-covalently functionalising the graphite in the presence of an aqueous solution of polymeric amphiphilic molecules, to provide a dispersion of non-covalently functionalised exfoliated pristine graphene flakes, optionally;
(i) via ultra-sonication, mild-sonication, shear-mixing or vortex-mixing; and/or
(ii) wherein the initial concentration of graphite is within the range of 5 to 20 mg/ml, preferably 10 mg/ml; and/or
(iii) wherein the initial concentration of polymeric amphiphilic molecules is within the range of 0.1 to 10 mg/ml; and/or
(iv) step c) is continued for up to 4 hours;
d) separating any remaining graphite from the dispersion of non-covalently functionalised exfoliated pristine graphene flakes produced in step c) optionally wherein the separating comprises
(i) mild centrifugation of the dispersion product of step c), preferably at 2000 rpm for 30 minutes, to sediment down any remaining graphite; and
(ii) decanting the supernatant containing the dispersion of non-covalently functionalised exfoliated pristine graphene flakes for further purification in accordance with step e);
e) purifying the dispersion of non-covalently functionalised exfoliated pristine graphene flakes produced in step d) to remove any excess polymeric amphiphilic molecules in solution which are not non-covalently attached to the exfoliated pristine graphene flakes, optionally wherein the purification process comprises;
(i) ultracentrifugation of the product of step d), preferably at 15,000-60,000 rpm for 60 minutes, to sediment down the non-covalently functionalised exfoliated pristine graphene flakes;
(ii) decanting the supernatant containing the excess polymeric amphiphilic molecules in solution which are not non-covalently attached to the exfoliated pristine graphene flakes;
(iii) redispersing the non-covalently functionalised exfoliated pristine graphene flakes in aqueous or alcoholic media, or pure water, preferably via sonication for two minutes; and
(iv) preferably repeating steps (i) to (iii) at least once; and
f) removing the solvent from the purified dispersion of non-covalently functionalised exfoliated pristine graphene flakes produced in step e), optionally via lyophillisation, to provide the dry graphene powder composition.

7. A stable homogenous dispersion comprising the dry graphene powder composition of any one of claims 1 to 5, re-dispersed in aqueous or alcoholic media wherein the media is free from dispersants or stabilizers.

8. The stable homogenous dispersion of claim 7, wherein;
a) the medium is an alcohol/water mixture; or
b) the medium is pure water; and/or
c) comprising, pristine graphene flakes at a concentration of up to 15 mg/ml;
and/or d) comprising, pristine graphene flakes at a concentration of 10 mg/ml.

9. A slurry or paste comprising, the dry graphene powder composition of any one of claims 1 to 5, in aqueous or alcoholic media.

10. A graphene ink for use in 2D or 3D printing comprising, the dry graphene powder composition of any one of claims 1 to 5, the stable homogeneous dispersion of any one of claims 7 to 8, or the slurry or paste of claim 9.

11. The graphene ink of claim 10 wherein;
a) the concentration of the graphene in the ink is within the range of 0.1 to 10 mg/ml;
and/or b) the surface tension of the ink is within the range of 60 to 80 mN/m, or 62 to 79 mN/m, or 64 to 78 mN/m, or 66 to 77 mN/m, or 68 to 76 mN/m, or 69 to 75 mN/m, or 70 to 74 mN/m; and/or
c) the viscosity of the ink is within the range of 1.0 to 2.1 mPas.

12. Use of the dry graphene powder of any one of claims 1 to 5, the stable homogeneous dispersion of any one of claims 7 to 8, the slurry or paste of claim 9, or the graphene ink of any one of claims 10 to 11, to produce a 3D or 2D printed article, including but not limited to a 3D or 2D printed article selected from the group comprising conductive circuits, electrode materials, and electrocatalyst layers/supports.

13. A 3D or 2D printed article, printed using the stable homogeneous dispersion of any one of claims 7 to 8, the slurry or paste of claim 9, or the graphene ink of any one of claims 10 to 11, including but not limited to a 3D or 2D printed article selected from the group comprising conductive circuits, electrode materials, and electrocatalyst layers/supports.

14. The 3D or 2D printed article of claim 13, wherein;
a) the conductivity measured as sheet resistance is better than 350 Ω/sq; and/or
b) the conductivity measured as sheet resistance is better than 35 Ω/sq; and/or
c) the conductivity measured as sheet resistance is approximately 30 Ω/sq; and/or
d) the conductivity measured as sheet resistance is approximately 30 Ω/sq, without the need for carrying out thermal annealing.

15. A process for printing the 2D article of any one of claims 13 to 14 comprising, printing the stable homogeneous dispersion of any one of claims 7 to 8, the slurry or paste of claim 9, or the graphene ink of any one of claims 10 to 11 onto a 2D substrate and then drying; optionally wherein the 2D substrate is a flexible substrate and/or wherein the 2D article is a flexible conductive circuit.

16. A process for printing the 3D article of any one of claims 13 to 14 comprising, printing the stable homogeneous dispersion of any one of claims 7 to 8, the slurry or paste of claim 9, or the graphene ink of any one of claims 10 to 11 into a coagulant bath containing a suitable coagulant, followed by removal from the bath, freezing and then drying, optionally further wherein;
a) the coagulant bath contains 1-10 wt % carboxymethylcellulose sodium salt (CMC) solution as the coagulant; and/or
b) the coagulant bath contains 5 wt % carboxymethylcellulose sodium salt (CMC) solution as the coagulant; and/or
c) freezing is carried out by immersing the 3D printed article in liquid nitrogen; and/or
d) drying is carried out by lyophilisation.

17. Use of the dry graphene powder of any one of claims 1 to 5, the stable homogeneous dispersion of any one of claims 7 to 8, the slurry or paste of claim 9, or the graphene ink of any one of claims 10 to 11, to produce pristine graphene fibers, or to fabricate a nanocomposite material incorporating pristine graphene.

18. Pristine graphene fibers manufactured from, or a nanocomposite material incorporating pristine graphene fabricated with, the dry graphene powder of any one of claims 1 to 5 the stable homogeneous dispersion of any one of claims 7 to 8, the slurry or paste of claim 9, or the graphene ink of any one of claims 10 to 11.

19. A process for wet-spinning pristine graphene fibers comprising, injecting the stable homogeneous dispersion of any one of claims 7 to 8, the slurry or paste of claim 9, or the graphene ink of any one of claims 10 to 11 into a coagulant bath containing a suitable coagulant, optionally wherein;
a) the stable homogeneous dispersion comprises the dry graphene powder composition of any one of claims 1 to 5, dispersed in aqueous medium; and/or
b) the stable homogeneous dispersion comprises the dry graphene powder composition of any one of claims 1 to 5, dispersed in aqueous poly(1-vinyl-3-ethylimidazolium bromide) solution; and/or
c) the stable homogeneous dispersion comprises PTEBS functionalised pristine graphene powder, dispersed in aqueous poly(1-vinyl-3-ethylimidazolium bromide) solution; and/or
d) the stable homogeneous dispersion comprises PTEBS functionalised pristine graphene powder, dispersed at 5 mg in aqueous poly(1-vinyl-3-ethylimidazolium bromide) solution (1 wt %); and/or
e) the coagulant bath contains 1-10 wt % carboxymethylcellulose sodium salt (CMC) solution as the coagulant; and/or
f) the coagulant bath contains 5 wt % carboxymethylcellulose sodium salt (CMC) solution as the coagulant.

20. A process for fabricating a nanocomposite material incorporating pristine graphene comprising forming a stable homogeneous dispersion including the dry graphene powder of any one of claims 1 to 5, and a solubilised matrix material, and inducing self-assembly of the pristine graphene with the matrix material, optionally wherein;
a) the matrix material is capable of forming a hydrogel; a composite, or aerogel; and/or
b) the matrix material is a protein, a peptide a polymer, a biopolymer, or an oligomer; and/or
c) the matrix material is silk fibroin; and/or
d) the stable homogeneous dispersion is formed by mixing graphene powder dispersed in aqueous media with an aqueous solution of matrix material; and/or
e) the stable homogeneous dispersion is formed by mixing graphene powder dispersed in water with an aqueous solution of silk fibroin; and/or
f) the stable homogeneous dispersion is formed by mixing graphene powder dispersed in water (at 2 mg/mL) with an aqueous solution of silk fibroin (at 30 wt %); and/or
g) the self-assembly is induced chemically or physically or electrically; and/or
h) the self-assembly is induced chemically by adding a cross-linking agent or adjusting the pH or electrolyte concentration of the homogeneous dispersion; or
i) the self-assembly is induced by evaporating the solvent of the homogeneous dispersion; or
j) the self-assembly is induced physically by sonication; or
k) the self-assembly is induced electrically by applying a DC current; or
l) the self-assembly is induced thermally by heating and/or cooling; or
m) the self-assembly is induced mechanically by shearing.
